(19) United States
(12) Patent Application Publication
(10) Pub. No.: US 2015/0101658 A1
(43) Pub. Date: Apr. 16, 2015

(54) PHOTOVOLTAIC DEVICE AND METHOD FOR MANUFACTURING SAME

(71) Applicant: SHARP KABUSHIKI KAISHA, Osaka-shi (JP)

(72) Inventors: Kazuhito Nishimura, Osaka-shi (JP); Yoshiyuki Nasuno, Osaka-shi (JP); Shinya Honda, Osaka-shi (JP); Takashi Yamada, Osaka-shi (JP)

(21) Appl. No.: 14/399,376

(22) PCT Filed: Apr. 15, 2013
(86) PCT No.: PCT/JP2013/061165

§ 371 Date: Nov. 6, 2014

(30) Foreign Application Priority Data
May 10, 2012 (JP) 2014-108705

(51) Int. Cl. H01L 31/18; H01L 31/0368; H01L 31/077

(52) U.S. Cl. CPC H01L 31/1824; H01L 31/077; H01L 31/03685
USPC 136/255; 438/97

(57) ABSTRACT

A photovoltaic device (10) includes a photovoltaic layer (3) in which a p-type semiconductor layer (31), an i-type semiconductor layer (32), and an n-type semiconductor layer (33) are successively stacked. The p-type semiconductor layer (31) is formed from a p-type thin silicon films (311 to 313). The p-type thin silicon films (311 and 312) are formed by depositing silicon thin films having a p-type conductivity type and then by nitriding the silicon thin films using pulse power in which a 100 Hz to 1 kHz low-frequency pulse power is superimposed on a 1 MHz and 50 MHz high-frequency power as plasma excitation power, and using conditions in which the density of the high-frequency power is 100 to 300 mW/cm², the pressure during plasma processing is 300 to 600 Pa, and the substrate temperature during plasma processing is 140° C. to 190° C. The p-type thin silicon film (313) is deposited under the above conditions.

### TECHNICAL FIELD

The present invention relates to a photovoltaic device and a method for manufacturing the same.

### BACKGROUND ART

In the related art, a photovoltaic device disclosed in PTL 1 as a photovoltaic device that converts light to electricity is known.

The photovoltaic device has a structure including at least one photovoltaic layer with a pin structure in which a p-type semiconductor layer including silicon atoms, an i-type semiconductor layer, and an n-type semiconductor layer are successively stacked.

The p-type semiconductor layer includes 0.001 to 10 (atomic %) of nitrogen atoms, and has a crystal silicon phase. As a result, an open-circuit voltage and a short-circuit current are increased, and it is possible to increase the photovoltaic efficiency.

In the related art, the photovoltaic device disclosed in PTL 2 is known. The photovoltaic device is formed with the same structure as the photovoltaic device disclosed in PTL 1, the p-type semiconductor layer thereof including nitrogen atoms at a concentration A (atomic %) and boron atoms at a concentration B (atomic %), and the concentration A and the concentration B satisfying the relationship 0.11−0.99 A+0.042 A²≦B≦0.2+0.2 A+0.05 A². As a result, an open-circuit voltage and a short-circuit current are increased, and it is possible to increase the photovoltaic efficiency.

PTL 3 discloses a method for manufacturing a conductive silicon nitride film. The method for manufacturing the conductive silicon nitride film includes a first step of forming an n-type or a p-type doped microcrystalline silicon film, and a second step of forming a conductive silicon nitride film by nitriding the microcrystalline silicon film by irradiating the microcrystalline silicon film with plasma including nitrogen, in which the dilution ratio of the raw material gas to be introduced when forming the microcrystalline silicon film in the first step is 150 or more and 600 or less.

As a result, it is possible to prepare a conductive silicon nitride film with a low refractive index and that has conductivity. It is possible to improve the photovoltaic efficiency by connecting the two photovoltaic layers that configure the photovoltaic device using the conductive silicon nitride film.

PTL 1: Japanese Patent No. 4441298

PTL 2: Japanese Patent No. 4215697

PTL 3: Japanese Unexamined Patent Application Publication No. 2011-198920

### DISCLOSURE OF INVENTION

In the method for preparing the p-type semiconductor layer disclosed in PTL 1 and PTL 2, nitrogen (N₂) gas is used as the raw material gas in the deposition step of the p-type semiconductor layer, and the concentration of nitrogen content in the film of the p-type semiconductor layer is controlled by controlling the flow rate ratio with respect to the silane (SiH₄) gas of the N₂ gas.

However, in the deposition step of the silicon semiconductor layer by plasma chemical vapor deposition (CVD) for manufacturing a thin film solar battery with a large area, it is difficult to realize a uniform concentration of nitrogen content in the entire plane of the photovoltaic device.

As a cause thereof, in the method for preparing the p-type semiconductor layer disclosed in PTLs 1 and 2, in the plasma CVD device with a large area such as an electrode area exceeding 1 m², it is thought that it is difficult to supply the raw material gas ensuring in-plane uniformity across the entire electrode area, and difficult to ensure in-plane uniformity of the decomposition energy of the N₂ gas due to distribution of the electric field strength in the electrode plane.

The conductive silicon nitride film disclosed in PTL 3 satisfies the characteristics demanded with respect to an intermediate layer arranged between the two photovoltaic layers. PTL 3 does not disclose the manufacturing conditions for achieving both an improvement in the open-circuit voltage with respect to the p-type semiconductor layer or the n-type semiconductor layer and maintenance of a high fill factor (FF).

The present invention provides a method for manufacturing a photovoltaic device with improved in-plane uniformity of nitrogen content concentration in a large-area photovoltaic device and that has high conversion efficiency.

The present invention provides a photovoltaic device with improved in-plane uniformity of nitrogen content concentration in a large-area photovoltaic device and that has high conversion efficiency.

According to an embodiment of the invention, the photovoltaic device that has a photovoltaic portion that converts light to electricity includes a substrate; and first and second silicon-based semiconductor layers. The first silicon-based semiconductor layer is arranged above the substrate, configures the photovoltaic portion, and has a p-type conductivity type. The second silicon-based semiconductor layer is arranged above the substrate, configures the photovoltaic portion, and has an n-type conductivity type. At least one of the first and second silicon-based semiconductor layers has a structure in which a layer including nitrogen atoms is interposed in a thickness direction between layers not including nitrogen atoms or a structure in which a layer having a first nitrogen atom concentration is interposed in the thickness direction between layers having a second nitrogen atom concentration lower than the first nitrogen atom concentration.

According to the embodiments of the invention, there is provided a method for manufacturing a photovoltaic device by a plasma CVD method, the method including a first plasma processing step of depositing the first silicon-based semiconductor layer that has a p-type conductivity type or an n-type conductivity type above the substrate; a second plasma processing step of irradiating the first silicon-based semiconductor layer with plasma in which a raw material gas including nitrogen atoms is excited; and a third plasma processing step of depositing a second silicon-based semiconductor layer that has the same conductivity type as the first silicon-based semiconductor layer on the first silicon-based semiconductor layer, in which the second plasma processing step uses pulsed power in which a low frequency pulse power of 100 Hz to 1 kHz is superimposed on a high frequency power of 1 MHz to 50 MHz as a plasma excitation power, in which the density of the high frequency power is 100 mW/cm² to 300 mW/cm², in which the pressure during the plasma processing is 300 Pa to 600 Pa, and in which the substrate temperature during plasma processing is 140° C. to 190° C.

The photovoltaic device according to the embodiment of the invention includes a first silicon-based semiconductor layer that has a p-type conductivity type, and a second silicon-based semiconductor layer that has an n-type conductivity type, in which at least one of the first and second silicon-based semiconductor layers has a structure in which a layer including nitrogen atoms is interposed in a thickness direction between layers not including nitrogen atoms or a structure in which a layer having a first nitrogen atom concentration is interposed in the thickness direction between layers having a second nitrogen atom concentration lower than the first nitrogen atom concentration.

According to the structure, since it is not necessary to excessively increase the concentration of nitrogen atoms in the conductive layer as a whole, it is possible to increase the open-circuit voltage without increasing the series resistance. Through the structure interposing the high nitrogen concentration layer with low nitrogen concentration layers, it is easy to realize a uniform nitrogen content over the entire large surface area substrate, and possible to improve the conversion efficiency over the entire surface of the large-area photovoltaic device as a result.

In the method for manufacturing a photovoltaic device according to the embodiment of the invention, a silicon-based semiconductor layer that has a p-type conductivity type or an n-type conductivity type is formed by nitriding the first silicon-based semiconductor layer along with depositing the first silicon-based semiconductor layer using a pulse power in which a low frequency pulse power of 100 Hz to 1 kHz is superimposed on a high frequency power of 1 MHz to 50 MHz as the plasma excitation power and conditions in which the density of the high frequency power is 100 mW/cm² to 300 mW/cm², the pressure during plasma processing is 300 Pa to 600 Pa, and the substrate temperature during plasma processing is 140° C. to 190° C. As a result, the discharge during forming of the silicon-based semiconductor layer having a p-type conductivity type or an n-type conductivity type becomes uniform in the entire substrate plane, and it is possible to increase the electrode in-plane uniformity of the decomposition ratio of the nitrogen gas.

Accordingly, the in-plane uniformity of the nitrogen atom concentration in the silicon-based semiconductor layer having a p-type conductivity type or an n-type conductivity type is improved, and the open-circuit voltage is improved by suppressing a lowering of the fill factor in the photovoltaic device.

Thereby, it is possible to improve the conversion efficiency of a large-area photovoltaic device.

### BRIEF DESCRIPTION OF DRAWINGS

FIG. 1 is a cross-sectional view showing a configuration of a photovoltaic device according to Embodiment 1 of the invention.

FIG. 2 is a cross-sectional view showing a separate configuration of a photovoltaic device according to Embodiment 1.

FIG. 3 is a cross-sectional view showing the configuration of a solar battery module.

FIG. 4 is an exploded perspective view of the solar battery module.

FIG. 5 is a schematic view showing a configuration of a plasma device that manufactures the photovoltaic device according to Embodiment 1.

FIG. 6 is a schematic view showing a separate configuration of a plasma device that manufactures the photovoltaic device according to Embodiment 1.

FIG. 7 is a conceptual view of the pulse power in the plasma device shown in FIG. 5 and the plasma device shown in FIG. 6.

FIG. 8 is a first process drawing showing a method for manufacturing the solar battery module shown in FIG. 3.

FIG. 9 is a second process drawing showing a method for manufacturing the solar battery module shown in FIG. 3.

FIG. 10 is a first process drawing showing a detailed processing of the step (c) shown in FIG. 8.

FIG. 11 is a second process drawing showing a detailed processing of the step (c) shown in FIG. 8.

FIG. 12 is a drawing showing the RF power dependency of the open-circuit voltage and the conversion efficiency.

FIG. 13 is a drawing showing the RF power dependency of the series resistance and the fill factor.

FIG. 14 is a drawing showing the film deposition pressure dependency of the open-circuit voltage and the conversion efficiency.

FIG. 15 is a drawing showing the film deposition pressure dependency of the series resistance and the fill factor.

FIG. 16 is a drawing showing the substrate temperature dependency of the open-circuit voltage and the conversion efficiency.

FIG. 17 is a drawing showing the substrate temperature dependency of the series resistance and the fill factor.

FIG. 18 is a drawing showing the duty ratio dependency of the open-circuit voltage and the conversion efficiency.

FIG. 19 is a drawing showing the duty ratio dependency of the series resistance and the fill factor.

FIG. 20 is a drawing showing the plasma processing time dependency of the open-circuit voltage and the conversion efficiency.

FIG. 21 is a drawing showing the plasma processing dependency of the series resistance and the fill factor.

FIG. 22 is a diagram showing the distribution in the depth direction of the nitrogen concentration and the boron concentration.

FIG. 23 is a cross-sectional view showing a configuration of a photovoltaic device according to Embodiment 2.

FIG. 24 is a first process drawing for describing the method of manufacturing the photovoltaic device shown in FIG. 23.

FIG. 25 is a second process drawing for describing the method of manufacturing the photovoltaic device shown in FIG. 23.

FIG. 26 is a third process drawing for describing the method of manufacturing the photovoltaic device shown in FIG. 23.

FIG. 27 is a cross-sectional view showing a separate configuration of a photovoltaic device according to Embodiment 2.

FIG. 28 is a first process drawing showing the method of manufacturing the photovoltaic device shown in FIG. 27.

FIG. 29 is a second process drawing showing the method of manufacturing the photovoltaic device shown in FIG. 27.

FIG. 30 is a third process drawing showing the method of manufacturing the photovoltaic device shown in FIG. 27.

FIG. 31 is a fourth process drawing showing the method of manufacturing the photovoltaic device shown in FIG. 27.

FIG. 32 is a fifth process drawing showing the method of manufacturing the photovoltaic device shown in FIG. 27.

### BEST MODE FOR CARRYING OUT THE INVENTION

Embodiments of the present invention will be described in detail referring to the accompanying drawings. The same or corresponding parts in the drawings are given the same reference signs, and description thereof will not be repeated.

In the specification, the term “amorphous phase” refers to a state in which the silicon (Si) atoms or the like are arranged randomly. The term “microcrystalline phase” refers to a state which crystal grains of Si or the like for which the grain diameter is several nm to several hundred are present in the random network of Si atoms or the like. Although amorphous silicon is denoted by “a-Si”, in practice, this denotation indicates the inclusion of hydrogen (H) atoms. For amorphous silicon carbide (a-SiC), amorphous silicon nitride (a-SiN), amorphous silicon germanium (a-SiGe), amorphous germanium (a-Ge), microcrystalline silicon carbide (μc-SiC), microcrystalline silicon nitride (μc-SiN), microcrystalline silicon (μc-Si), microcrystalline silicon germanium (μc-SiGe) and microcrystalline germanium (μc-Ge), the inclusion of H atoms is similarly indicated.

### Embodiment 1

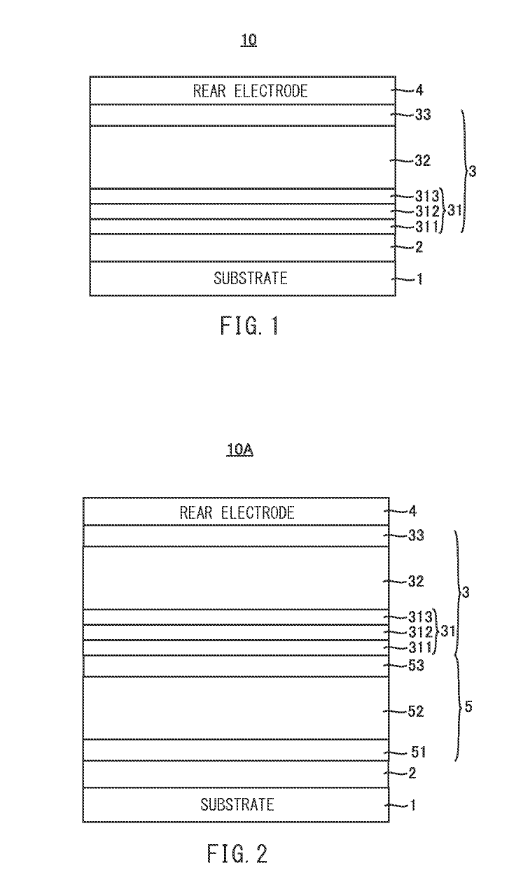

FIG. 1 is a cross-sectional view showing a configuration of a photovoltaic device according to Embodiment 1. With reference to FIG. 1, the photovoltaic device 10 according to Embodiment 1 of the invention includes a substrate 1, a transparent conductive film 2, and photovoltaic layer 3, and a rear electrode 4.

The photovoltaic layer 3 includes a p-type semiconductor layer 31, an i-type semiconductor layer 32, and an n-type semiconductor layer 33. The p-type semiconductor layer 31 is formed from a p-type silicon thin films 311 to 313.

The transparent conductive film 2 is arranged in contact with the substrate 1.

The photovoltaic layer 3 has a structure in which the p-type semiconductor layer 31, the i-type semiconductor layer 32, and the n-type semiconductor layer 33 are successively stacked on the transparent conductive film 2, and is arranged in contact with the transparent conductive film 2.

The p-type semiconductor layer 31 is arranged in contact with the transparent conductive film 2. More specifically, the p-type silicon thin film 311 of the p-type semiconductor layer 31 is arranged in contact with the transparent conductive film 2, the p-type silicon thin film 312 is arranged in contact with the p-type silicon thin film 311, and the p-type silicon thin film 313 is arranged in contact with the p-type silicon thin film 312.

The i-type semiconductor layer 32 is arranged in contact with the p-type silicon thin film 313 of the p-type semiconductor layer 31, and the n-type semiconductor layer 33 is arranged in contact with the i-type semiconductor layer 32.

The rear electrode 4 is formed from a two-layer structure of a transparent conductive film and a reflective layer. The transparent conductive film of the rear electrode 4 is arranged in contact with the n-type semiconductor layer 33 of the photovoltaic layer 3, and the reflection layer is arranged in contact with the transparent conductive film.

The substrate 1 is formed from an insulating glass, or, in a case in which flexibility is provided, a resin such as a polyimide.

The transparent conductive film 2 is formed, for example, from indium tin oxide (ITO), SnO₂, ZnO or the like.

Each of the p-type silicon thin films 311 and 313 is formed from any one of a p-type a-SiC, a p-type a-SiN, a p-type a-Si, a p-type a-SiGe, a p-type μc-SiC, a p-type μc-SiN, a p-type μc-Si, and a p-type μc-SiGe.

The p-type silicon thin film 312 is formed from any one of a p-type a-SiC, a p-type a-SiN, a p-type a-Si, a p-type a-SiGe, a p-type μc-SiC, a p-type μc-SiN, a p-type μc-Si, and a p-type μc-SiGe to which nitrogen atoms are added. In a case in which the p-type silicon thin film 312 is formed from the same p-type a-SiN or a p-type μc-SiN as the p-type silicon thin films 313 and 311, the nitrogen concentration of the p-type silicon thin film 312 is higher than the nitrogen concentration of the p-type silicon thin films 311 and 313.

Accordingly, the p-type semiconductor layer 31 has a structure in which a layer including nitrogen atoms (p-type silicon thin film 312) is interposed in the thickness direction between layers not including nitrogen atoms (p-type silicon thin films 311 and 313) or a structure in which a layer that has a first nitrogen atom concentration (p-type silicon thin film 312) is interposed in the thickness direction between layers that have a second nitrogen atom concentration lower than the first nitrogen layer concentration (p-type silicon thin films 311, 313).

The i-type semiconductor layer 32 is formed from any one of an i-type a-SiC, an i-type a-SiN, an i-type a-Si, an i-type a-SiGe, an i-type a-Ge, an i-type μc-SiC, an i-type μc-SiN, an i-type μc-Si, an i-type μc-SiGe, and an i-type μc-Ge. In a case in which the i-type semiconductor layer 32 is formed from any of an i-type a-SiC, an i-type a-SiN, an i-type a-SiGe, an i-type μc-Sic, an i-type μc-SiN, and an i-type μc-SiGe, the optical band gap may become gradually smaller from the incident side of light toward the rear surface side.

The n-type semiconductor layer 33 is formed from any of an n-type a-SiC, an n-type a-SiN, an n-type a-Si, an n-type a-SiGe, an n-type μc-SiC, an n-type μc-SiN, an n-type μc-Si, and an n-type μc-SiGe.

In this way, the p-type semiconductor layer 31, the i-type semiconductor layer 32, and the n-type semiconductor layer 33 are each formed from a silicon-based semiconductor layer.

The p-type semiconductor layer 31, the i-type semiconductor layer 32, and the n-type semiconductor layer 33 may be alternately formed from the same silicon-based semiconductor layer, or may be alternately formed from different silicon-based semiconductor layers. For example, the p-type semiconductor layer 31 and the i-type semiconductor layer 32 may be formed from microcrystalline silicon, and the n-type semiconductor layer 33 may be formed by amorphous silicon. In addition, the p-type semiconductor layer 31 may be formed from amorphous silicon carbide, the i-type semiconductor layer 32 may be formed from microcrystalline silicon, and the n-type semiconductor layer 33 may be formed by amorphous silicon.

Each of the i-type semiconductor layer 32 and the n-type semiconductor layer 33 may be formed with a single layer structure or may be formed with a multi-layer structure. In a case in which each of the i-type semiconductor layer 32 and the n-type semiconductor layer 33 is formed with a multi-layer structure, the plurality of layers may be alternately formed from the same silicon-based semiconductor layer, or may be alternately formed from different silicon-based semiconductor layer.

The transparent conductive film that configures the rear electrode 4 is formed from ITO, SnO₂, ZnO, or the like. The transparent conductive film that configures the rear electrode 4 may be formed from the same material as the transparent conductive film 2, or may be formed from a different material from the transparent conductive film 2.

The reflective layer that configures the rear electrode 4 is formed from a metal film with a high reflectivity, such as silver (Ag) and aluminum (Al), or a TiO₂ or the like with a high reflectivity to the color white.

The structure of the photovoltaic device 10 described above is a structure in a case of sunlight being incident from the substrate 1 side is referred to as a superstrate-type.

The photovoltaic device 10 may be a substrate type in which sunlight is incident from the rear electrode 4 side. In this case, a reflection electrode is formed on the substrate 1 instead of the transparent conductive film 2, the n-type semiconductor layer 33, the i-type semiconductor layer 32, and the p-type semiconductor layer 31 may be successively stacked on the reflection electrode, and a transparent conductive film may be formed on the p-type semiconductor layer 31.

FIG. 2 is a cross-sectional view showing a separate configuration of a photovoltaic device according to Embodiment 1. The photovoltaic device according to Embodiment 1 may be the photovoltaic device 10A shown in FIG. 2.

With reference to FIG. 2, the photovoltaic device 10A has the photovoltaic layer 5 added to the photovoltaic device 10 shown in FIG. 1, and is otherwise the same as the photovoltaic device 10.

The photovoltaic layer 5 is arranged between the transparent conductive film 2 and the photovoltaic layer 3. The photovoltaic layer 5 has a structure in which the p-type semiconductor layer 51, the i-type semiconductor layer 52 and the n-type semiconductor layer 53 are successively stacked on the transparent conductive film 2.

The p-type semiconductor layer 51 is arranged in contact with the transparent conductive film 2, the i-type semiconductor layer 52 is arranged in contact with p-type semiconductor layer 51, and the n-type semiconductor layer 53 is arranged in contact with the i-type semiconductor layer 52.

In the photovoltaic device 10A, the p-type silicon thin film 311 of the p-type semiconductor layer 31 is arranged in contact with the n-type semiconductor layer 53 of the photovoltaic layer 5.

The p-type semiconductor layer 51 is formed from any one of a p-type a-SiC, a p-type a-SiN, a p-type a-Si, a p-type a-SiGe, a p-type μc-SiC, a p-type μc-SiN, a p-type μc-Si, and a p-type μc-SiGe.

The i-type semiconductor layer 52 is formed from any one of an i-type a-SiC, an i-type a-SiN, an i-type a-Si, an i-type a-SiGe, an i-type a-Ge, an i-type μc-SiC, an i-type μc-SiN, an i-type μc-Si, and i-type μc-SiGe, and an i-type μc-Ge. In a case in which the i-type semiconductor layer 52 is formed from any of an i-type a-SiC, an i-type a-SiN, an i-type a-SiGe, an i-type μc-Sic, an i-type μc-SiN, and an i-type μc-SiGe, the optical band gap may become gradually smaller from the incident side of light toward the rear surface side.

The n-type semiconductor layer 53 is formed from any of an n-type a-SiC, an n-type a-SiN, an n-type a-Si, an n-type a-SiGe, an n-type μc-SiC, an n-type μc-SiN, an n-type μc-Si, and an n-type μc-SiGe.

In this way, the p-type semiconductor layer 51, the i-type semiconductor layer 52, and the n-type semiconductor layer 53 are each formed from a silicon-based semiconductor layer. The p-type semiconductor layer 51, the i-type semiconductor layer 52, and the n-type semiconductor layer 53, similarly to the above-described p-type semiconductor layer 31, the i-type semiconductor layer 32, and the n-type semiconductor layer 33, may be alternately formed from the same silicon-based semiconductor layer, or may be alternately formed from different silicon-based semiconductor layers.

In the photovoltaic device 10A, the p-type semiconductor layer 51 of the photovoltaic layer 5 may be formed, similarly to the p-type semiconductor layer 31, from a structure in which a layer including nitrogen atoms is interposed in the thickness direction between layers not including nitrogen atoms or a structure in which a layer that has a first nitrogen atom concentration is interposed in the thickness direction between layers that have a second nitrogen atom concentration lower than the first nitrogen atom concentration.

Above, the photovoltaic device 10 including one photovoltaic layer 3 and the photovoltaic device 10A including two photovoltaic layers 3 and 5 were described. However, Embodiment 1 is not limited thereto, and the photovoltaic device according to Embodiment 1 may be formed from a structure in which three or more photovoltaic layers are stacked in the thickness direction, and ordinarily includes at least one photovoltaic layer formed from a pin structure, in which at least one of the p-type semiconductor layer and the n-type semiconductor layer in at least one photovoltaic layer may be formed from a structure in which a layer including nitrogen atoms is interposed in the thickness direction between layers not including nitrogen atoms or a structure in which a layer that has a first nitrogen atom concentration is interposed in the thickness direction between layers that have a second nitrogen atom concentration lower than the first nitrogen atom concentration.

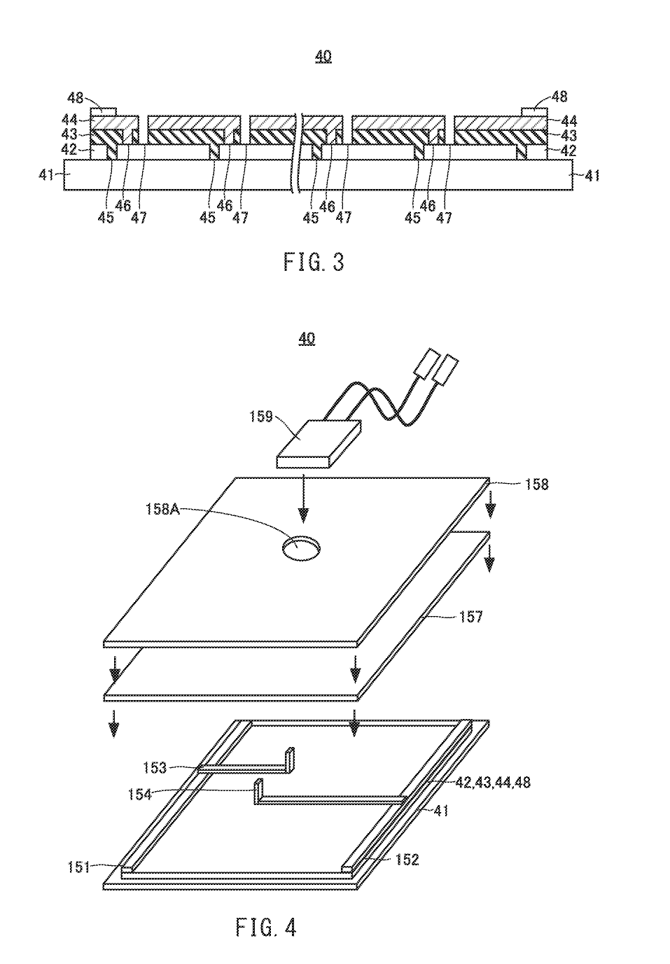

FIG. 3 is a cross-sectional view showing the configuration of a solar battery module. With reference to FIG. 3, the solar battery module 40 includes a substrate 41, a transparent conductive film 42, a photovoltaic layer 43, a rear electrode 44, and an electrode 48.

The substrate 41 is formed from the same material as the substrate 1, described above.

The transparent conductive film 42 is arranged on the substrate 41 spaced with an isolation groove 45 in the in-plane direction of the substrate 41, and is formed from the same material as the above-described transparent conductive film 2.

The photovoltaic layer 43 is arranged on the transparent conductive film 42 so that the isolation groove 45 is embedded. In this case, the photovoltaic layer 43 is arranged via the contact line 46 in the in-plane direction of the substrate 41. The photovoltaic layer 43, for example, is formed from photovoltaic layer 3 shown in FIG. 1 or the two photovoltaic layers 3 and 5 shown in FIG. 2, and is ordinarily formed from one or more photovoltaic layers (having a pin structure).

The rear electrode 44 is arranged on the photovoltaic layer 43 such that the contact line 46 is embedded. In this case, the rear electrode 44 is arranged spaced by the isolation groove 47 in the in-plane direction of the substrate 41. The rear electrode 44 is formed from the same material as the rear electrode 4, described above.

The electrode 48 is arranged on the rear electrode 44 at both end portions in the in-plane direction of the substrate 41.

In the solar battery module 40, one photovoltaic layer 43 is interposed by the transparent conductive film 42 and the rear electrode 44, and the rear electrode 44 is connected to the transparent conductive film 42 that contacts the neighboring photovoltaic layer 43. As a result, the solar battery module 40 is formed from structure in which a plurality of photovoltaic layers 43 is connected in series in the in-plane direction of the substrate 41, referred to as a so-called integrated solar battery. The photoelectric current photogenerated in the solar battery module 40 is extracted from two electrodes 48. In this way, in the solar battery module 40, one group of the transparent conductive film 42, the photovoltaic layer 43, and the rear electrode 44 are formed from the photovoltaic device 10 shown in FIG. 1 or the photovoltaic device 10A shown in FIG. 2.

FIG. 4 is an exploded perspective view of the solar battery module. With reference to FIG. 4, the solar battery module 40 further includes bus bars 151 and 152, lead lines 153 and 154, a sealing material 157, a back sheet 158 and a terminal box 159.

The bus bar 151 is electrically connected to one electrode 48, and the bus bar 152 is electrically connected to the other electrode 48.

The lead line 153 is electrically connected to the bus bar 151, and the lead line 154 is electrically connected to the bus bar 152.

The sealing material 157 has the same through hole as the through hole 158A formed in the back sheet 158. The sealing material 157 and the back sheet 158 are stacked on the transparent conductive film 42, the photovoltaic layer 43, the rear electrode 44, the electrode 48, the bus bars 151 and 152, and the lead lines 153 and 154, and is heated and pressed. The terminal box 159 is electrically connected to one end of the lead lines 153 and 154 via a through hole 158A.

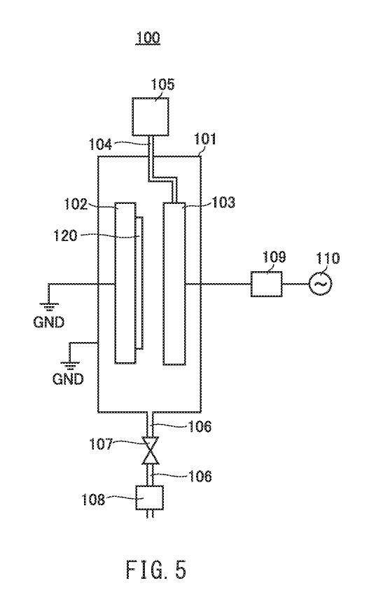

FIG. 5 is a schematic view showing a configuration of a plasma device that manufactures the photovoltaic device according to Embodiment 1.

With reference to FIG. 5, the plasma device 100 includes a chamber 101, an anode electrode 102, the cathode electrode 103, a supply pipe 104, a gas supply device 105, an exhaust pipe 106, a gate valve 107, a pump 108, an impedance matching circuit 109, and a power source 110.

The chamber 101 is electrically connected to the ground potential GND. The anode electrode 102 and the cathode electrode 103 have a plate shape and are arranged substantially parallel in the chamber 101. The anode electrode 102 is electrically connected to the ground potential GND, and the cathode electrode 103 is connected to the impedance matching circuit 109. The anode electrode 102 has a built-in heater and supports the substrate 120. The cathode electrode 103 has a plurality of holes (not shown) for supplying the raw material gas to a discharge region between the anode electrode 102 and the cathode electrode 103 in the surface of the anode electrode 102 side. The areas of the anode electrode 102 and the cathode electrode 103, are, for example, 1.65 m².

One end of the supply pipe 104 is connected to the gas supply device 105, and the other end thereof is connected to the cathode electrode 103.

The gas supply device 105 is connected to the supply pipe 104. The gas supply device 105 supplies silane (SiH₄) gas, nitrogen (N₂) gas, hydrogen (H₂) gas, methane (CH₄) gas, diborane (B₂H₆) gas and phosphine (PH₃) gas to the interior of the cathode electrode 103 via the supply pipe 104.

One end of the exhaust pipe 106 is connected to the chamber 101. The gate valve 107 is arranged in the exhaust pipe 106 on the chamber 101 side. The pump 108 is arranged in the exhaust pipe 106 further to the downstream side than the gate valve 107. The pump 108 is used as a dry pump.

The gate valve 107 sets the pressure in the chamber 101 to a desired pressure. The pump 108 exhausts the gas inside the chamber 101 via the gate valve 107.

The impedance matching circuit 109 is connected between the cathode electrode 103 and the power source 110. The impedance matching circuit 109 supplies power to the cathode electrode 103 by adjusting the impedance so that a reflected wave of power supplied from the power source 110 reaches a minimum.

The power source 110 supplies pulse power in which a lower frequency pulse with a frequency of 100 Hz to 1 kHz is superimposed on a high frequency power with a frequency of 1 MHz to 50 MHz to the impedance matching circuit 109.

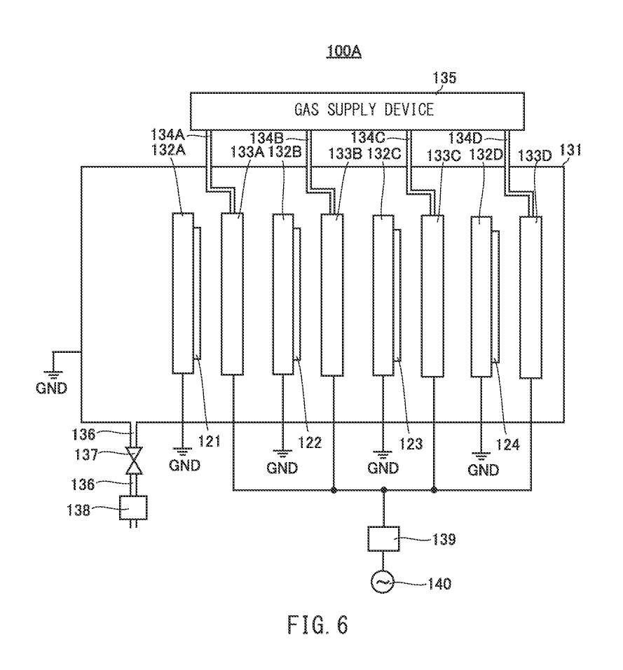

FIG. 6 is a schematic view showing a separate configuration of a plasma device that manufactures the photovoltaic device according to Embodiment 1.

With reference to FIG. 6, the plasma device 100A includes a chamber 131, anode electrodes 132A to 132D, cathode electrodes 133A to 133D, a supply pipe 134A to 134D, a gas supply device 135, an exhaust pipe 136, a gate valve 137, a pump 138, an impedance matching circuit 139, and a power source 140.

The chamber 131 is electrically connected to the ground potential GND. The anode electrodes 132A to 132D and the cathode electrodes 133A to 133D have plate shapes. The anode electrode 132A and the cathode electrode 133A are arranged substantially parallel in the chamber 131. The anode electrode 132B and the cathode electrode 133B are arranged substantially parallel in the chamber 131. The anode electrode 132C and the cathode electrode 133C are arranged substantially parallel in the chamber 131. The anode electrode 132D and the cathode electrode 133D are arranged substantially parallel in the chamber 131.

The anode electrodes 132A to 132D are electrically connected to the ground potential GND, and the cathode electrodes 133A to 133D are connected to the impedance matching circuit 139. The anode electrodes 132A to 132D have a built-in heaters, and support the substrates 121 to 124, respectively. The cathode electrode 133A has a plurality of holes (not shown) for supplying the raw material gas to a discharge region between the anode electrode 132A and the cathode electrode 133A in the surface of the anode electrode 132A. The cathode electrode 133B has a plurality of holes (not shown) for supplying the raw material gas to a discharge region between the anode electrode 132B and the cathode electrode 133B in the surface of the anode electrode 132B side. The cathode electrode 133C has a plurality of holes (not shown) for supplying the raw material gas to a discharge region between the anode electrode 132C and the cathode electrode 133C in the surface of the anode electrode 132C side. The cathode electrode 133D has a plurality of holes (not shown) for supplying the raw material gas to a discharge region between the anode electrode 132D and the cathode electrode 133D in the surface of the anode electrode 132D side. The areas of the anode electrodes 132A to 132D and the cathode electrodes 133A to 133D, are, for example, 1.65 m².

The supply pipe 134A is connected between the gas supply device 135 and the cathode electrode 133A. The supply pipe 134B is connected between the gas supply device 135 and the cathode electrode 133B. The supply pipe 134C is connected between the gas supply device 135 and the cathode electrode 133C. The supply pipe 134D is connected between the gas supply device 135 and the cathode electrode 133D.

The gas supply device 135 is connected to the supply pipes 134A to 134D. The gas supply device 135 supplies SiH₄ gas, N₂ gas, H₂ gas, CH₄ gas, B₂H₆ gas and PH₃ gas to the interior of the cathode electrodes 133A to 133D via the supply pipes 134A to 134D.

One end of the exhaust pipe 136 is connected to the chamber 131. The gate valve 137 is arranged in the exhaust pipe 136 on the chamber 131 side. The pump 138 is arranged in the exhaust pipe 136 further to the downstream side than the gate valve 137. The pump 138 is used as a dry pump.

The gate valve 137 sets the pressure in the chamber 131 to a desired pressure. The pump 138 exhausts the gas inside the chamber 131 via the gate valve 137.

The impedance matching circuit 139 is connected between the cathode electrodes 133A to 133D and the power source 140. The impedance matching circuit 139 supplies power to the cathode electrodes 133A to 133D by adjusting the impedance so that a reflected wave of power supplied from the power source 140 reaches a minimum.

The power source 140 supplies pulse power in which a lower frequency pulse with a frequency of 100 Hz to 1 kHz is superimposed on a high frequency power with a frequency of 1 MHz to 50 MHz to the impedance matching circuit 139.

In this way, the plasma device 100A supplies the pulse power by one power source 140 to the four cathode electrodes 133A to 133D.

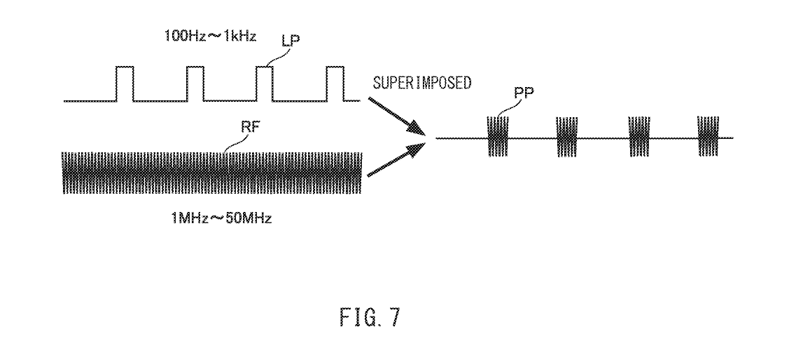

FIG. 7 is a conceptual view of the pulse power in the plasma device 100 shown in FIG. 5 and the plasma device 100A shown in FIG. 6.

With reference to FIG. 7, the power sources 110 and 140 generate a lower frequency pulse power LP and a high frequency power RF, generate the pulse power PP by superimposing the generated low frequency pulse power LP on the high frequency power RF, and supply the generated pulse power PP to each of the impedance matching circuits 109 and 139.

The lower frequency pulse power LP has a frequency 100 Hz to 1 kHz, and the high frequency power RF has a frequency of 1 MHz to 50 MHz. As a result, the pulse power PP is formed from power in which the high frequency power is intermittently expressed at a frequency of 100 Hz to 1 kHz.

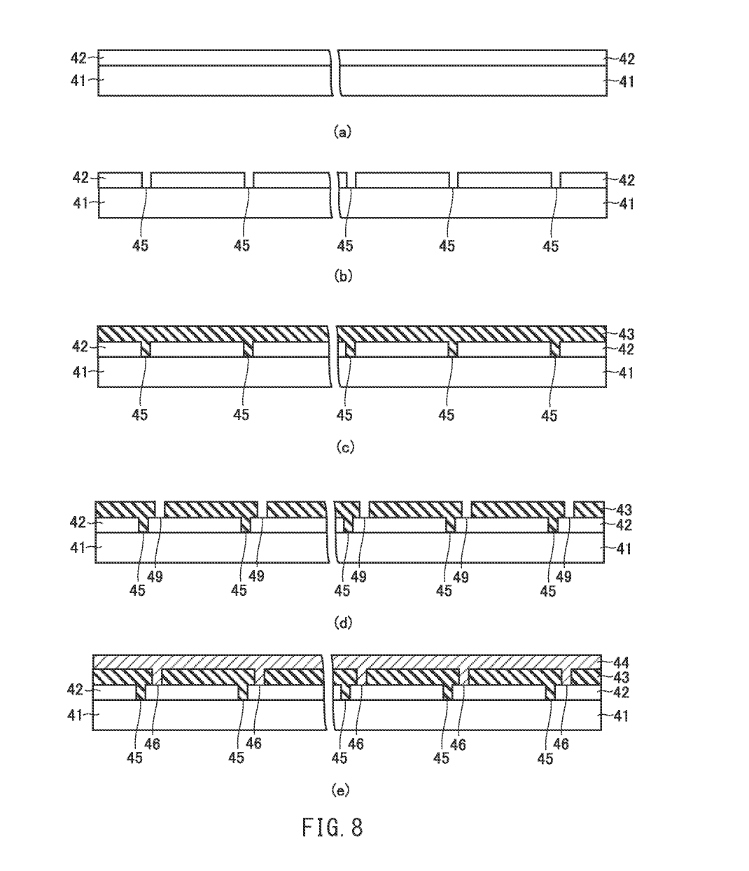

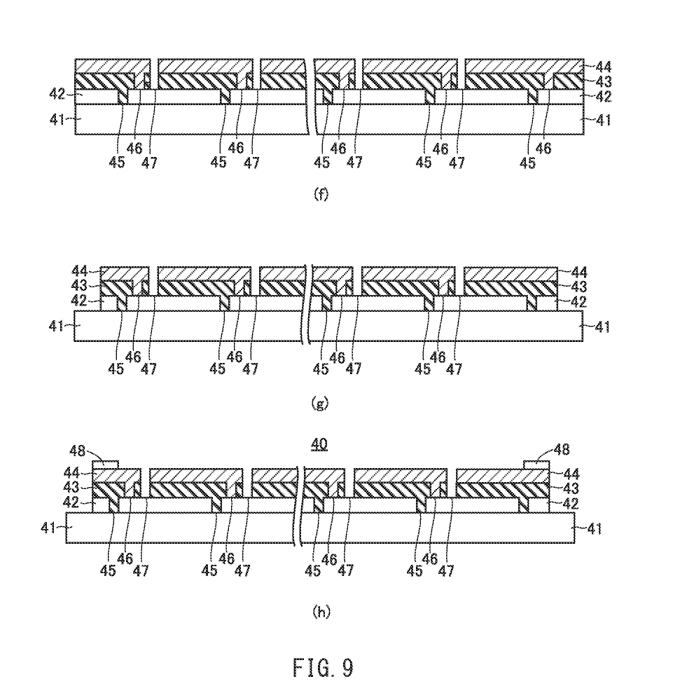

FIGS. 8 and 9 are first and second process drawings, respectively, showing a method for manufacturing the solar battery module 40 shown in FIG. 3.

In FIGS. 8 and 9, a method for manufacturing the solar battery module 40 is described with a case in which the photovoltaic layer 43 of the solar battery module 40 is formed from two photovoltaic layers 5 and 3 shown in FIG. 2, and the substrate 41, the transparent conductive film 42, the p-type semiconductor layer 51, the i-type semiconductor layer 52, the n-type semiconductor layer 53, the p-type semiconductor layer 31, the i-type semiconductor layer 32, the n-type semiconductor layer 33, and the rear electrode 44 are formed from the following materials. The photovoltaic layer 5 arranged on the light incident side is defined as the top layer, and the photovoltaic layer 3 is defined as the bottom layer.

The substrate 41 is formed from an insulating glass, and the transparent conductive film 42 is formed from SnO₂. The p-type semiconductor layer 51 is formed from a p-type a-SiC, and the p-type dopant is boron (B). The i-type semiconductor layer 52 is formed from an i-type a-Si. The n-type semiconductor layer 53 is formed from a two-layer structure (n-type a-Si/n-type μc-Si) in which n-type μc-Si is stacked on n-type a-Si, and the n-type dopant is phosphorous (P).

The p-type semiconductor layer 31 is formed from a p-type μc-Si, and the p-type dopant is B. Each of the p-type silicon thin films 311 and 313 are formed from a p-type μc-Si, and the p-type silicon thin film 312 is formed from a p-type μc-SiN. The i-type semiconductor layer 32 is formed from an i-type μc-Si. The n-type semiconductor layer 33 is formed from a two-layer structure (n-type a-Si/n-type μc-Si) in which n-type μc-Si is stacked on n-type a-Si, and the n-type dopant is P.

The rear electrode 44 is formed from a two-layer structure of a transparent conductive film and a reflection layer, the transparent conductive film is formed from ZnO, and the reflection layer is formed from Ag.

When manufacturing of the solar battery module 40 is started, a transparent conductive film 42 formed from SnO₂ is formed on the substrate 41 (refer to step (a) in FIG. 8). In this case, the size of the substrate 41 is, for example, 1000 mm×1400 mm.

The transparent conductive film 42 is irradiated with laser light from the substrate 41 side, and the isolation groove 45 is formed in the transparent conductive film 42 (refer to step (b) in FIG. 8). In this case, the isolation groove 45 is formed with a pitch of, for example, 10 mm. The laser light is formed from a YAG laser with a second harmonic (wavelength: 532 nm) or a yttrium orthovanadate (YVO₄) laser with a second harmonic (wavelength: 532 nm).

After step (b), the photovoltaic layer 5 and the photovoltaic layer 3 are successively stacked on the transparent conductive film 42 by a plasma CVD method, and the photovoltaic layer 43 is formed such that the isolation groove 45 is embedded (refer to step (c) in FIG. 8).

The photovoltaic layer 43 is irradiated with laser light from the substrate 41 side, and the isolation groove 49 is formed in the photovoltaic layer 43 (refer to step (d) in FIG. 8). In this case, the isolation groove 49 is formed with a pitch of, for example, 10 mm. The above-described laser light is used for the laser light.

After the step (d), a transparent conductive film formed from ZnO is deposited on the photovoltaic layer 43 by a sputtering method, a reflection layer formed from Ag is subsequently deposited on the transparent conductive film by a sputtering method, and the rear electrode 44 is formed such that the isolation groove 49 is embedded (refer to step (e) in FIG. 8). In this case, the film thickness of the transparent conductive film (=ZnO) is, for example, 40 nm to 100 nm, and the film thickness of the reflection layer (=Ag) is, for example, 50 nm to 200 nm. The isolation groove 49 becomes the contact line 46 by forming the rear electrode 44.

After the step (e), the photovoltaic layer 43 and the rear electrode 44 are irradiated with laser light from the substrate 41 side, and the isolation groove 47 is formed in the photovoltaic layer 43 and the rear electrode 44 (refer to step (f) in FIG. 9). In this case, the isolation groove 47 is formed with a pitch of, for example, 10 mm.

Thereafter, the transparent conductive film 42, the photovoltaic layer 43, and the rear electrode 44 are irradiated with laser light from the substrate 41 side, and a trimming region is formed by removing the transparent conductive film 42, photovoltaic layer 43, and the rear electrode 44 at the peripheral edge portion of the substrate 41 (refer to step (g) in FIG. 9).

An electrode 48 is formed on the rear electrode 44 at both end portions in the in-plane direction of the substrate 41 (refer to step (h) in FIG. 9). Thereafter, as described above, the bus bars 151 and 152 are electrically connected to the electrode 48, the lead lines 153 and 154 are electrically connected to the bus bars 151 and 152, respectively, the sealing material 157 and the back sheet 158 are stacked, heated and pressed, and the terminal box 159 is connected to the lead lines 153 and 154, thereby completing the solar battery module 40.

The number of integration steps (=number of series connections of the photovoltaic layer 43 isolated by the contact line 46) in the solar battery module 40 is, for example, 45.

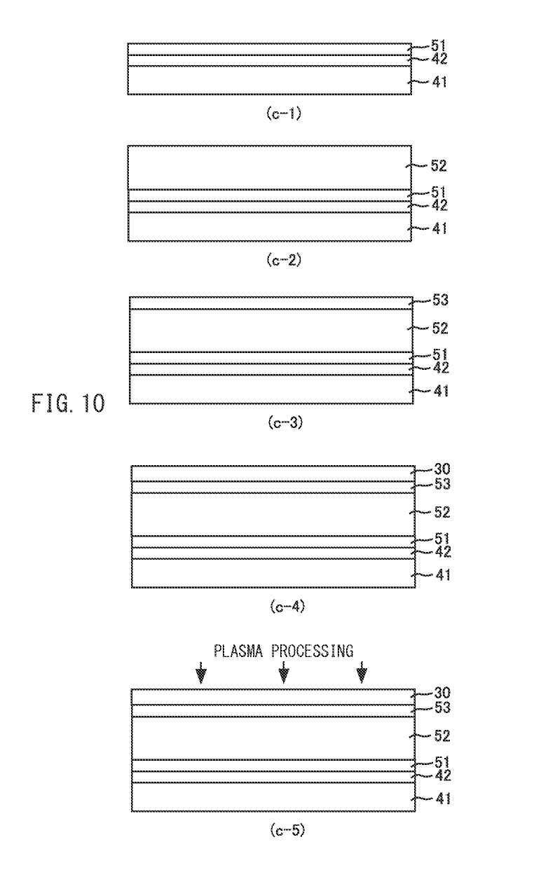

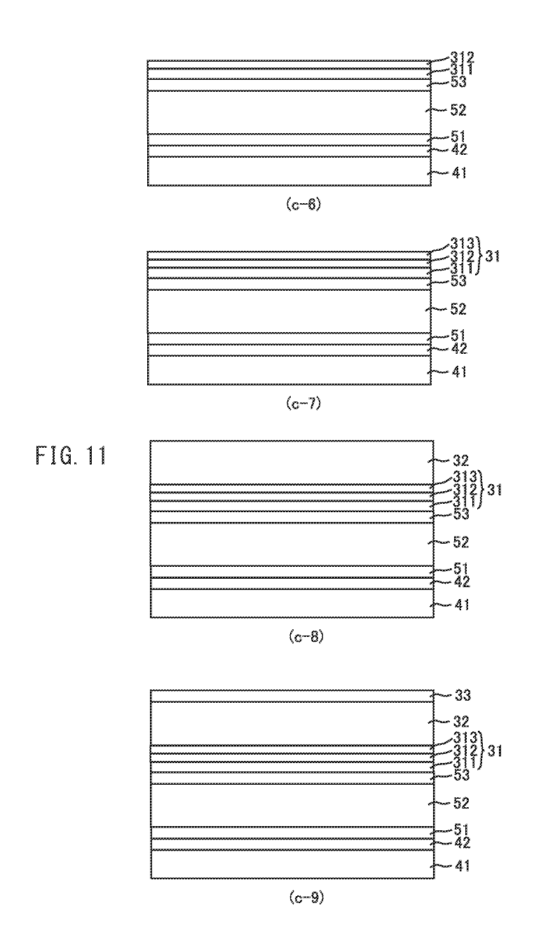

FIGS. 10 and 11 are a first and a second process drawings, respectively, showing a detailed processing of the step (c) shown in FIG. 8.

Although FIGS. 10 and 11 illustrate process drawings of forming the photovoltaic layer 43 on one transparent conductive film 42, in practice, the photovoltaic layer 43 is formed on a plurality of transparent conductive films 42 isolated by the isolation grooves 45.

The flow rates of the raw material gas for forming the p-type semiconductor layer 51, the i-type semiconductor layer 52, the n-type semiconductor layer 53, the p-type semiconductor layer 31, the i-type semiconductor layer 32, and the n-type semiconductor layer 33 are shown in Table 1.

TABLE 1

| | | | B₂H₆/ | | | |
|---|---|---|---|---|---|---|
| | SiH₄ | H₂ | H₂ | PH₃/H₂ | CH₄ | N₂ |
| | (sccm) | (sccm) | (sccm) | (sccm) | (sccm) | (sccm) |
| p-type | 2 | 42 | 12 | — | 16 | — |
| semiconductor | | | | | | |
| layer 51 | | | | | | |
| i-type | 10 | 100 | — | — | — | — |
| semiconductor | | | | | | |
| layer 52 | | | | | | |
| n-type | 20 | 150 | — | 50 | — | — |
| semiconductor | 4 | 250 | — | 25 | — | — |
| layer 53 | | | | | | |
| p-type silicon | 2 | 120 | 12 | — | — | — |
| thin film 30 | | | | | | |
| Plasma | — | — | — | — | — | Flow |
| processing | | | | | | rate |
| | | | | | | where |
| | | | | | | N₂/SiH₄ |
| | | | | | | flow |
| | | | | | | rate |
| | | | | | | ratio is |
| | | | | | | 5% |
| p-type silicon | 2 | 120 | 12 | — | — | — |
| thin film 313 | | | | | | |
| i-type | 2 | 120 | — | — | — | — |
| semiconductor | | | | | | |
| layer 32 | | | | | | |
| n-type | 20 | 150 | — | 50 | — | — |
| semiconductor | 4 | 250 | — | 25 | — | — |
| layer 33 | | | | | | |

After the step (b) shown in FIG. 8, the substrate 41 on which the transparent conductive film 42 is formed is installed on the anode electrodes 132A to 132D of the plasma device 100A as the substrates 121 to 124.

The gas supply device 135 supplies 2 sccm of SiH₄ gas, 42 sccm of H₂ gas, 12 sccm of hydrogen diluted B₂H₆ gas, and 16 sccm of CH₄ gas to the interior of the respective cathode electrodes 133A to 133D via the supply pipes 134A to 134D. Thereby, the SiH₄ gas, the H₂ gas, the B₂H₆ gas and the CH₄ gas are supplied to the discharge region between the anode electrode 132A and the cathode electrode 133A, the discharge region between the anode electrode 132B and the cathode electrode 133B, the discharge region between the anode electrode 132C and the cathode electrode 133C, and the discharge region between the anode electrode 132D and the cathode electrode 133D. The concentration of the hydrogen diluted B₂H₆ gas is, for example, 0.1%.

The pressure inside the chamber 131 is set to 600 Pa to 1000 Pa using the gate valve 137. The temperature of the substrates 121 to 124 is set to 170° C. to 200° C. using heaters built into the anode electrodes 132A to 132D.

The power source 140 applies the pulse power PP to the cathode electrodes 133A to 133D via the impedance matching circuit 139. In this case, the frequency of the low frequency pulse power LP is, for example, 300 Hz to 500 Hz, and the frequency of the high frequency power RF is, for example, 11 MHz to 14 MHz. The power of the high frequency power in the pulse power PP is, for example, 20 mW/cm² to 500 mW/cm².

Thereby, plasma is generated between the anode electrode 132A and the cathode electrode 133A, between the anode electrode 132B and the cathode electrode 133B, between the anode electrode 132C and the cathode electrode 133C, and between the anode electrode 132D and the cathode electrode 133D, and the p-type semiconductor layer 51 formed from a p-type a-SiC is deposited on the transparent conductive film 42 (refer to step (c-1) in FIG. 10).

When the film thickness of the p-type semiconductor layer 51 is 5 nm to 20 nm, the gas supply device 135 increases the flow rate of the SiH₄ gas from 2 sccm to 10 sccm, increases the flow rate of the H₂ gas from 42 sccm to 100 sccm, and stops the B₂H₆ gas and the CH₄ gas. Thereby, the i-type semiconductor layer 52 formed from an i-type a-Si is deposited on the p-type semiconductor layer 51 (refer to step (c-2) in FIG. 10).

When the film thickness of the i-type semiconductor layer 52 is 220 nm to 320 nm, the gas supply device 135 increases the flow rate of the SiH₄ gas from 10 sccm to 20 sccm, increases the flow rate of the H₂ gas from 100 sccm to 150 sccm, and supplies 50 sccm of the hydrogen diluted PH₃ gas to the interior of the cathode electrodes 133A to 133D, respectively, via the supply pipes 134A to 134D. Thereby, the n-type a-Si is deposited on the i-type semiconductor layer 52. The concentration of the hydrogen diluted PH₃ gas is, for example, 0.2%.

When the film thickness of the n-type a-Si is the desired film thickness, the gas supply device 135 decreases the flow rate of the SiH₄ gas from 20 sccm to 4 sccm, increases the flow rate of the H₂ gas from 150 sccm to 250 sccm, and decreases the flow rate of the PH₃ gas from 50 sccm to 25 sccm. Thereby, the n-type μc-Si is deposited on the n-type a-Si. That is, the n-type semiconductor layer 53 formed from an n-type a-Si/n-type μc-Si is deposited on the i-type semiconductor layer 52 (refer to step (c-3) in FIG. 10).

The film thickness of the n-type semiconductor layer 53 formed from an n-type a-Si/n-type μc-Si is, for example, 5 nm to 30 nm; however the ratio of the film thickness n-type a-Si and the film thickness of the n-type μc-Si is arbitrary.

When the film thickness of the n-type semiconductor layer 53 formed from an n-type a-Si/n-type μc-Si is 5 nm to 30 nm, the gas supply device 135 decreases the flow rate of the SiH₄ gas from 4 sccm to 2 sccm, decreases the flow rate of the H₂ gas from 250 sccm to 120 sccm, and stops the PH₃ gas, and supplies 12 sccm of hydrogen diluted B₂H₆ gas to the interior of the cathode electrodes 133A to 133D, respectively, via the supply pipes 134A to 134D. The heater built into the anode electrodes 132A to 132D sets the temperature of the substrates 121 to 124 to 140° C. to 170° C., and the gate valve 137 sets the pressure of the chamber 131 to 400 Pa to 1600 Pa. Thereby, the p-type silicon thin film 30 formed from a p-type μc-Si is deposited on the n-type semiconductor layer 53 (refer to step (c-4) in FIG. 10).

When the film thickness of the p-type silicon thin film 30 is the desired value, the gas supply device 135 stops the SiH₄ gas, the H₂ gas, and the B₂H₆ gas, and supplies the N₂ gas at a flow rate ratio of N₂/SiH₄ of 5% to the interior of the cathode electrodes 133A to 133D via the supply pipes 134A to 134D, respectively. Although a range of 1% to 10% can be used as the N₂/SiH₄ flow rate ratio, 5% is used herein.

Thereby, plasma employing N₂ gas is generated between the anode electrode 132A and the cathode electrode 133A, between the anode electrode 132B and the cathode electrode 133B, between the anode electrode 132C and the cathode electrode 133C, and between the anode electrode 132D and the cathode electrode 133D, and the p-type silicon thin film 30 is treated by plasma employing N₂ gas (refer to step (c-5) in FIG. 10).

As a result, the p-type silicon thin films 311 and 312 are formed (refer to step (c-6) in FIG. 11). The p-type silicon thin film 311 is formed from a p-type μc-Si not including nitrogen atoms, and the p-type silicon thin film 312 is formed from a p-type μc-SiN including nitrogen atoms. The term “not including nitrogen atoms” indicates that the concentration of nitrogen atom content is the equal to or lower than the base layer (layer to which nitrogen atoms are not actively added) of the p-type silicon thin film 311.

After the step (c-6), the gas supply device 135 stops the N₂ gas, and supplies 2 sccm of SiH₄ gas, 120 sccm of H₂ gas, 12 sccm of hydrogen diluted B₂H₆ gas to the interior of the respective cathodes 133A to 133D via the supply pipes 134A to 134D.

Thereby, the p-type silicon thin film 313 formed from a p-type μc-Si is deposited on the p-type silicon thin film 312, and the p-type semiconductor layer 31 is deposited on the n-type semiconductor layer 53 (refer to step (c-7) in FIG. 11).

The film thickness of the p-type semiconductor layer 31 formed from the p-type silicon thin films 311 to 313 is, for example, 5 nm to 30 nm. The overall film thickness of the p-type silicon thin films 311 and 312 is the same as the film thickness of the p-type silicon thin film 30 deposited in step (c-4). Accordingly, the ratio of the overall film thickness of the p-type silicon thin films 311 and 312 and the film thickness of the p-type silicon thin film 313 is arbitrary.

When the film thickness of the p-type semiconductor layer 31 formed from the p-type silicon thin films 311 to 313 is 5 nm to 30 nm, the gas supply device 135 stops the B₂H₆ gas. Thereby, the i-type semiconductor layer 32 formed from an i-type μc-Si is deposited on the p-type semiconductor layer 31 (refer to step (c-8) in FIG. 11).

When the film thickness of the i-type semiconductor layer 32 is 1200 nm to 2000 nm, the gas supply device 135 increases the flow rate of the SiH₄ gas from 2 sccm to 20 sccm, increases the flow rate of the H₂ gas from 120 sccm to 150 sccm, and supplies the hydrogen diluted PH₃ gas to the interior of the cathode electrodes 133A to 133D via the supply pipes 134A to 134D, respectively. Thereby, the n-type a-Si is deposited on the i-type semiconductor layer 32.

When the film thickness of the n-type a-Si is the desired film thickness, the gas supply device 135 decreases the flow rate of the SiH₄ gas from 20 sccm to 4 sccm, increases the flow rate of the H₂ gas from 150 sccm to 250 sccm, and decreases the flow rate of the PH₃ gas from 50 sccm to 25 sccm. Thereby, the n-type μc-Si is deposited on the n-type a-Si. That is, the n-type semiconductor layer 33 formed from an n-type a-Si/n-type μc-Si is deposited on the i-type semiconductor layer 32 (refer to step (c-9) in FIG. 11).

The film thickness of the n-type semiconductor layer 33 formed from an n-type a-Si/n-type μc-Si is, for example, 60 nm to 80 nm; however the ratio of the film thickness of the n-type a-Si and the film thickness of the n-type μc-Si is arbitrary.

When the film thickness of the n-type semiconductor layer 33 formed from an n-type a-Si/n-type μc-Si is 60 nm to 80 nm, the gas supply device 135 stops the SiH₄ gas, the H₂ gas and the PH₃ gas, the gate valve 137 is opened fully, and the pump 138 evacuates the inside of the chamber 131 to a vacuum. The heaters built into the anode electrodes 132A to 132D is turned off.

When the temperature of the substrates 121 to 124 is room temperature, the sample is extracted from the chamber 131.

In this way, the photovoltaic layer 43 is formed in one chamber 131 by a plasma CVD method. As a result, it is possible to eliminate the time for transport from the chamber for forming the photovoltaic layer 5 to the chamber for forming the photovoltaic layer 3, and shorten the time for preparing the photovoltaic layer 43, compared to a case of forming the two photovoltaic layers 5 and 3 that configure the photovoltaic layer 43 with separate chambers. Accordingly, it is possible to increase the production rate of the solar battery module 40.

The photovoltaic layer 43 is formed using the plasma device 100A in which one power source 140 supplies the power PP to a plurality of cathode electrodes 133A to 133D. Accordingly, it is possible to reduce the cost of the plasma device for manufacturing a plurality of solar battery modules 40.

Since the photovoltaic layer 43 is manufactured by continuously depositing the p-type semiconductor layer 51, the i-type semiconductor layer 52, the n-type semiconductor layer 53, the p-type semiconductor layer 31, the i-type semiconductor layer 32 and the n-type semiconductor layer 33 on the substrate 41 with a plasma CVD method, it is possible to suppress the mixing of impurities such as oxygen into the interface between the p-type semiconductor layer 51 and the i-type semiconductor layer 52, the interface between the i-type semiconductor layer 52 and the n-type semiconductor layer 53, the interface between the n-type semiconductor layer 53 and the p-type semiconductor layer 31, the interface between the p-type semiconductor layer 31 and the i-type semiconductor layer 32, and the interface between the i-type semiconductor layer 32 and the n-type semiconductor layer 33, and possible to manufacture a high quality photovoltaic layer 43.

The electrical characteristics of the solar battery module 40 manufactured by the above-described method are measured by irradiating AM 1.5 (intensity: 100 mW/cm²) simulated solar light at a temperature of 25° C. from the substrate 41 side. The conversion efficiency is calculated by dividing the maximum output power of the solar battery module 40 directly after being irradiated by simulated solar light by the area of the solar battery module 40.

Experiments were performed on changes in the electrical characteristics due to the RF power, the film deposition pressure, the substrate temperature, the duty ratio and the plasma processing time in the method for manufacturing the solar battery module 40. Below, the experimental results will be described.

The frequency of the lower frequency pulse power LP when the following experiments on the RF power, the film deposition pressure, the substrate temperature, the duty ratio and the plasma processing time were performed was to 400 Hz for the following reasons.

In a case in which the frequency of the low frequency pulse power LP is changed, because discharge is not stably continued in a range of less than 100 Hz and a range exceeding 1 kHz, it is understood that a range of 100 kHz to 1 kHz is appropriate for the frequency of the low frequency pulse power LP. In particular, this is because when the frequency of the low frequency pulse power LP is in a range of 300 Hz to 500 Hz, the discharge stability is excellent in all four discharge regions (regions between the anode electrodes 132A to 132D and the cathode electrodes 133A to 133D), and variations in the characteristics of the photovoltaic device are reduced.

(RF Power Dependency)

The RF power dependency of the electrical characteristics (open-circuit voltage Voc, series resistance Rs, short-circuit current Isc, the fill factor FF and the conversion efficiency) are shown in Table 2.

TABLE 2

| RF power | | | | | Conversion |
|---|---|---|---|---|---|
| [mW/cm²] | Voc[V] | Rs[Ω] | Isc[A] | FF | efficiency [%] |
| 20 | 61.0 | 1.95 | 3.52 | 0.722 | 11.1 |
| 60 | 61.8 | 1.95 | 3.52 | 0.722 | 11.2 |
| 100 | 62.4 | 1.97 | 3.52 | 0.725 | 11.4 |
| 150 | 62.8 | 1.97 | 3.53 | 0.725 | 11.5 |
| 200 | 62.9 | 1.98 | 3.53 | 0.728 | 11.5 |
| 300 | 62.9 | 2.00 | 3.52 | 0.722 | 11.4 |
| 400 | 62.9 | 2.40 | 3.52 | 0.712 | 11.3 |
| 500 | 62.8 | 3.00 | 3.52 | 0.700 | 11.1 |

The results shown in Table 2 are the electrical characteristics when the film deposition pressure is set to 400 Pa, the substrate temperature is set to 160° C., the frequency of the high frequency power RF is set to 11 MHz, the frequency of the low frequency pulse power LP is set to 400 Hz, the duty ratio of the low frequency pulse power LP is set to 0.25, and the high frequency power RF is changed to 20 mW/cm², 60 mW/cm², 100 mW/cm², 150 mW/cm², 200 mW/cm², 300 mW/cm², 400 mW/cm², and 500 mW/cm². The areas of the substrates 121 to 124 is 14000 cm², and the pulse power PP is supplied to four cathode electrodes 133A to 133D from one power supply 140.

As shown in Table 2, a conversion efficiency of 11.1% or more is obtained in a case in which the high frequency power RF is changed in a range of 20 mW/cm² to 500 mW/cm².

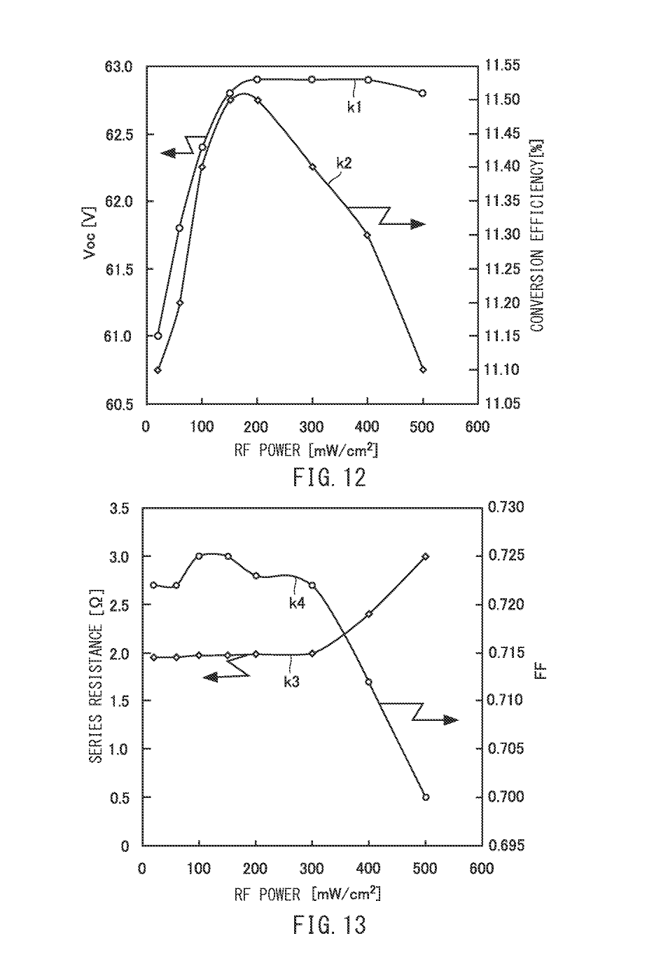

FIG. 12 is a drawing showing the RF power dependency of the open-circuit voltage Voc and the conversion efficiency RF. FIG. 13 is a drawing showing the RF power dependency of the series resistance and the fill factor FF.

In FIG. 12, the vertical axis indicates the open-circuit voltage Voc and the conversion efficiency, and the horizontal axis indicates the RF power. The curve k1 indicates the RF power dependency of the open-circuit voltage Voc, and the curve k2 indicates the RF power dependency of the conversion efficiency.

In FIG. 13, the vertical axis indicates the series resistance and the fill factor FF, and the horizontal axis indicates the RF power. The curve k3 indicates the RF power dependency of the series resistance, and the curve k4 indicates the RF power dependency of the fill factor FF.

The fill factor FF is held at a value of 0.720 or more with the RF power in a range up to 300 mW/cm², and sharply decreases when the RF power exceeds 300 mW/cm² (refer to curve k4). This is because when the RF power exceeds 300 mW/cm², the series resistance sharply increases (refer to curve k3).

The open-circuit voltage Voc becomes higher than 62 V at an RF power of 100 mW/cm² or more; however, the open-circuit voltage Voc greatly decreases at an RF power of less than 100 mW/cm² (refer to curve k1). In this way, the effect of an improvement in the open-circuit voltage Voc is not seen at an RF power of less than 100 mW/cm².

As a result, a conversion efficiency of 11.4% or more is obtained with the RF power in a range of 100 mW/cm² to 300 mW/cm².

Accordingly, it is understood that a range of 100 mW/cm² to 300 mW/cm² is appropriate for the RF power. Using a range of 100 mW/cm² to 300 mW/cm² as the RF power is preferable, since it is possible to decrease variations in the conversion efficiency of the manufactured solar battery module even in a manufacturing step in which the variations in the RF power stemming from variations in the hardware setting of the plasma device 100A and the power source characteristics are present.

(Film Deposition Dependency)

The film deposition pressure dependency of the electrical characteristics (open-circuit voltage Voc, series resistance Rs, short-circuit current Isc, the fill factor FF and the conversion efficiency) are shown in Table 3.

TABLE 3

| Film deposition | | | | | Conversion |
|---|---|---|---|---|---|
| pressure [Pa] | Voc[V] | Rs[Ω] | Isc[A] | FF | efficiency [%] |
| 100 | 62.4 | 2.80 | 3.51 | 0.702 | 11.0 |
| 200 | 62.5 | 2.20 | 3.51 | 0.716 | 11.2 |
| 300 | 62.7 | 1.97 | 3.52 | 0.725 | 11.4 |
| 400 | 62.8 | 1.97 | 3.53 | 0.725 | 11.5 |
| 500 | 62.6 | 1.96 | 3.53 | 0.724 | 11.4 |
| 600 | 62.3 | 1.95 | 3.52 | 0.724 | 11.3 |
| 700 | 61.2 | 1.95 | 3.52 | 0.723 | 11.1 |
| 800 | 60.5 | 1.94 | 3.52 | 0.723 | 11.0 |

The results shown in Table 3 are the electrical characteristics when RF power is set to 150 mW/cm², the substrate temperature is set to 160° C., the frequency of the high frequency power RF is set to 11 MHz, the frequency of the low frequency pulse power LP is set to 400 Hz, the duty ratio of the low frequency pulse power LP is set to 0.25, and the film deposition pressure is changed to 100 Pa, 200 Pa, 300 Pa, 400 Pa, 500 Pa, 600 Pa, 700 Pa, and 800 Pa. The areas of the substrates 121 to 124 is 14000 cm², and the pulse power PP is supplied to four cathode electrodes 133A to 133D from one power supply 140.

As shown in Table 3, a conversion efficiency of 11.0% or more is obtained in a case in which the film deposition pressure is changed in a range of 100 Pa to 800 Pa.

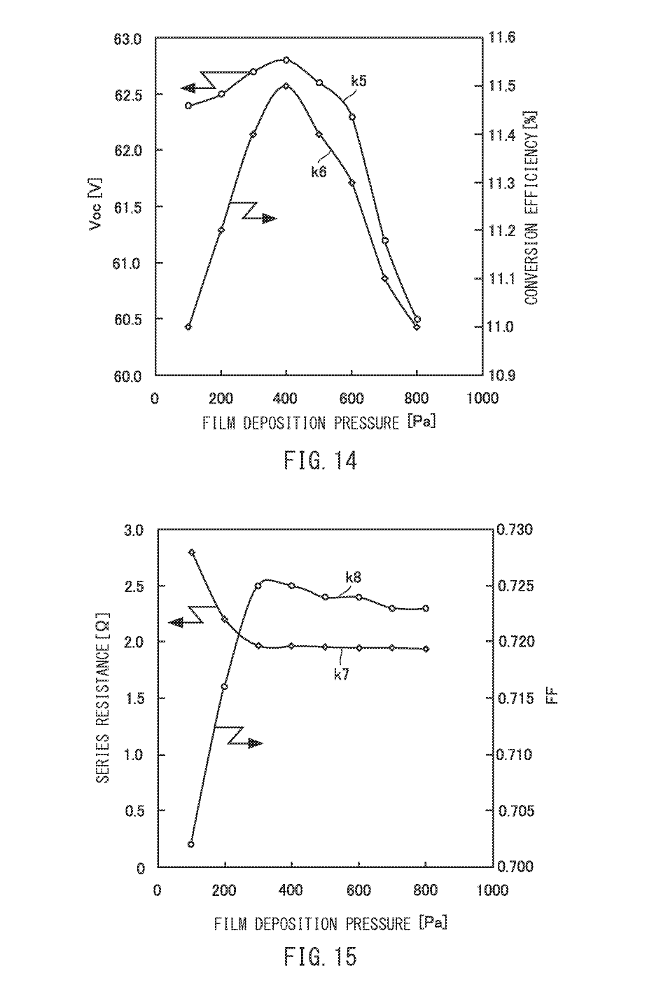

FIG. 14 is a drawing showing the film deposition pressure dependency of the open-circuit voltage Voc and the conversion efficiency. FIG. 15 is a drawing showing the film deposition pressure dependency of the series resistance and the fill factor FF.

In FIG. 14, the vertical axis indicates the open-circuit voltage Voc and the conversion efficiency, and the horizontal axis indicates the film deposition pressure. The curve k5 indicates the film deposition pressure dependency of the open-circuit voltage Voc, and the curve k6 indicates the film deposition pressure dependency of the conversion efficiency.

In FIG. 15, the vertical axis indicates the series resistance and the fill factor FF, and the horizontal axis indicates the film deposition pressure. The curve k7 indicates the film deposition pressure dependency of the series resistance, and the curve k8 indicates the film deposition pressure dependency of the fill factor FF.

The fill factor FF is held at a value of 0.720 or more with a film deposition pressure of 300 Pa or more, and sharply decreases when the film deposition pressure is less than 300 Pa (refer to curve k8). This is because when the film deposition pressure is less than 300 Pa, the decomposition ratio of the N₂ gas in the periphery of the electrodes (anode electrodes 132A to 132D and cathode electrodes 133A to 133D) increases, and the series resistance of the photovoltaic portion manufactured at a position corresponding to the peripheral portion of the electrode sharply increases (refer to curve k7).

The open-circuit voltage Voc is held at 62 V or more with a film deposition pressure of up to 600 Pa, and greatly decreases because the in-plane uniformity of the decomposition ratio of the N₂ gas decreases in the plane of the electrodes (anode electrodes 132A to 132D and cathode electrodes 133A to 133D) when the film deposition pressure exceeds 600 Pa (refer to curve k5).

As a result, a conversion efficiency of 11.3% or more is obtained with the film deposition pressure in a range of 300 Pa to 600 Pa.

Accordingly, it is understood that a range of 300 Pa to 600 Pa is appropriate for the film deposition pressure. Using a range of 300 Pa to 600 Pa as the film deposition pressure is preferable, since it is possible to decrease variations in the conversion efficiency of the manufactured solar battery module even in a manufacturing step in which the variations in the film deposition pressure stemming from variations in the vacuum exhaust capability and the pressure sensor of the plasma device 100A are present.

(Substrate Temperature Dependency)

The substrate temperature dependency of the electrical characteristics (open-circuit voltage Voc, series resistance Rs, short-circuit current Isc, the fill factor FF and the conversion efficiency) are shown in Table 4.

TABLE 4

| Substrate | | | | | Conversion |
|---|---|---|---|---|---|
| temperature [° C.] | Voc[V] | Rs[Ω] | Isc[A] | FF | efficiency [%] |
| 120 | 62.5 | 2.10 | 3.35 | 0.700 | 10.5 |
| 130 | 63.0 | 2.05 | 3.45 | 0.710 | 11.0 |
| 140 | 62.8 | 1.99 | 3.51 | 0.722 | 11.4 |
| 160 | 62.8 | 1.97 | 3.53 | 0.725 | 11.5 |
| 180 | 62.2 | 1.96 | 3.53 | 0.724 | 11.4 |
| 190 | 61.5 | 1.95 | 3.54 | 0.724 | 11.3 |
| 200 | 60.5 | 1.94 | 3.54 | 0.723 | 11.1 |

The results shown in Table 4 are the electrical characteristics when RF power is set to 150 mW/cm², the film deposition pressure is set to 400 Pa, the frequency of the high frequency power RF is set to 11 MHz, the frequency of the low frequency pulse power LP is set to 400 Hz, the duty ratio of the low frequency pulse power LP is set to 0.25, and the substrate temperature is changed to 120° C., 130° C., 140° C., 160° C., 180° C., 190° C., and 200° C. The area of the substrates 121 to 124 is 14000 cm², and the pulse power PP is supplied to four cathode electrodes 133A to 133D from one power supply 140.

As shown in Table 4, a conversion efficiency of 10.5% or more is obtained in a case in which the substrate temperature is changed in a range of 120° C. to 200° C.

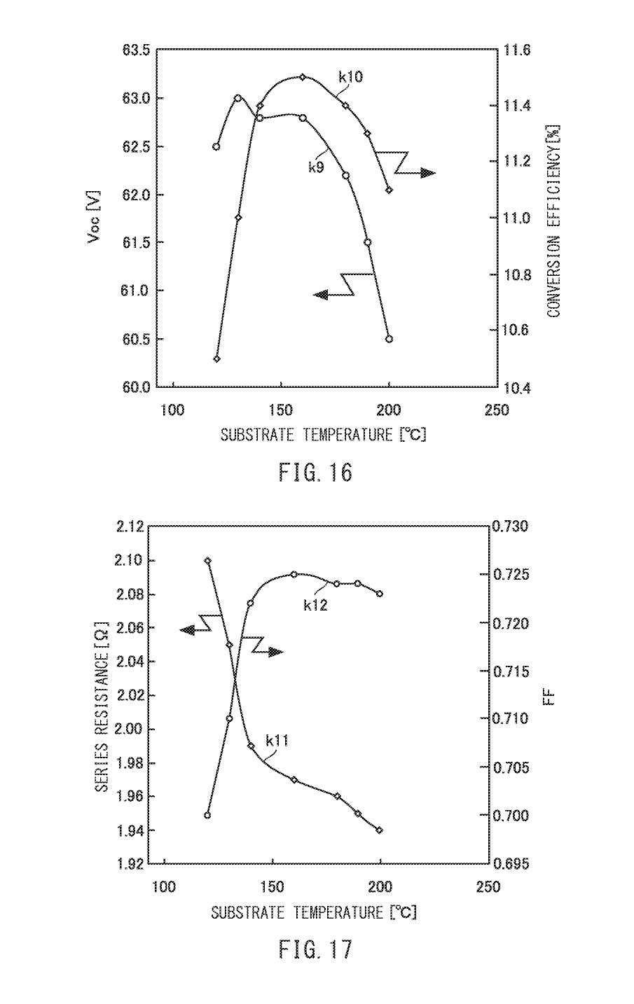

FIG. 16 is a drawing showing the substrate temperature dependency of the open-circuit voltage Voc and the power conversion efficiency. FIG. 17 is a drawing showing the substrate temperature dependency of the series resistance and the fill factor FF.

In FIG. 16, the vertical axis indicates the open-circuit voltage Voc and the conversion efficiency, and the horizontal axis indicates the substrate temperature. The curve k9 indicates the substrate temperature dependency of the open-circuit voltage Voc, and the curve k10 indicates the substrate temperature dependency of the conversion efficiency.

In FIG. 17, the vertical axis indicates the series resistance and the fill factor FF, and the horizontal axis indicates the substrate temperature. The curve k11 indicates the substrate temperature dependency of the series resistance, and the curve k12 indicates the substrate temperature dependency of the fill factor FF.

The fill factor FF is held at a value of 0.720 or more with a substrate temperature of 140° C. or more, and sharply decreases when the substrate temperature is less than 140° C. (refer to curve k12). This is because the series resistance greatly increases at a substrate temperature of less than 140° C. (refer to curve k11).

The open-circuit voltage Voc is held at a higher value than 61.5 V at a substrate temperature up to 190° C., and greatly decreases when the substrate temperature exceeds 190° C. because the optical band gap of the p-type semiconductor layers 31 and 51 and the i-type semiconductor layers 32 and 52 is decreased by reducing the hydrogen concentration in the films of the p-type semiconductor layers 31 and 51 and the i-type semiconductor layers 32 and 52 (refer to curve k9).

At a substrate temperature of less than 140° C., the short circuit current Isc greatly decreases because the optical band gap of the i-type semiconductor layers 32 and 52 increases (refer to Table 4).

As a result, a conversion efficiency of 11.3% or more is obtained with the substrate temperature in a range of 140° C. to 190° C. (refer to curve 10).

Accordingly, it is understood that a range of 140° C. to 190° C. is appropriate for the substrate temperature.

(Duty Ratio Dependency)

The duty ratio dependency of the electrical characteristics (open-circuit voltage Voc, series resistance Rs, short-circuit current Isc, the fill factor FF and the conversion efficiency) are shown in Table 5.

TABLE 5

| Duty | | | | | Conversion |
|---|---|---|---|---|---|
| Ratio | Voc[V] | Ra[Ω] | Isc[A] | FF | efficiency [%] |
| 0.05 | 61.2 | 1.94 | 3.51 | 0.720 | 11.0 |
| 0.10 | 62.0 | 1.94 | 3.51 | 0.728 | 11.3 |
| 0.20 | 62.5 | 1.95 | 3.52 | 0.728 | 11.4 |
| 0.25 | 62.7 | 1.95 | 3.53 | 0.725 | 11.5 |
| 0.30 | 62.6 | 1.96 | 3.53 | 0.724 | 11.4 |
| 0.40 | 62.4 | 1.98 | 3.52 | 0.724 | 11.4 |
| 0.50 | 62.3 | 2.00 | 3.52 | 0.720 | 11.3 |
| 0.60 | 62.2 | 2.50 | 3.50 | 0.710 | 11.1 |
| 1.00 | 60.5 | 3.00 | 3.45 | 0.695 | 10.4 |

The results shown in Table 5 are the electrical characteristics when RF power is set to 150 mW/cm², the film deposition pressure is set to 400 Pa, the substrate temperature is set to 160° C., the frequency of the high frequency power RF is set to 11 MHz, the frequency of the low frequency pulse power LP is set to 400 Hz, the duty ratio of the low frequency pulse power LP is set to 0.05, 0.10, 0.20, 0.25, 0.30, 0.40, 0.50, 0.60, and 1.00. The areas of the substrates 121 to 124 is 14000 cm², and the pulse power PP is supplied to four cathode electrodes 133A to 133D from one power supply 140.

As shown in Table 5, a conversion efficiency of 10.4% or more is obtained in a case in which the duty ratio is changed in a range of 0.05 to 1.00.

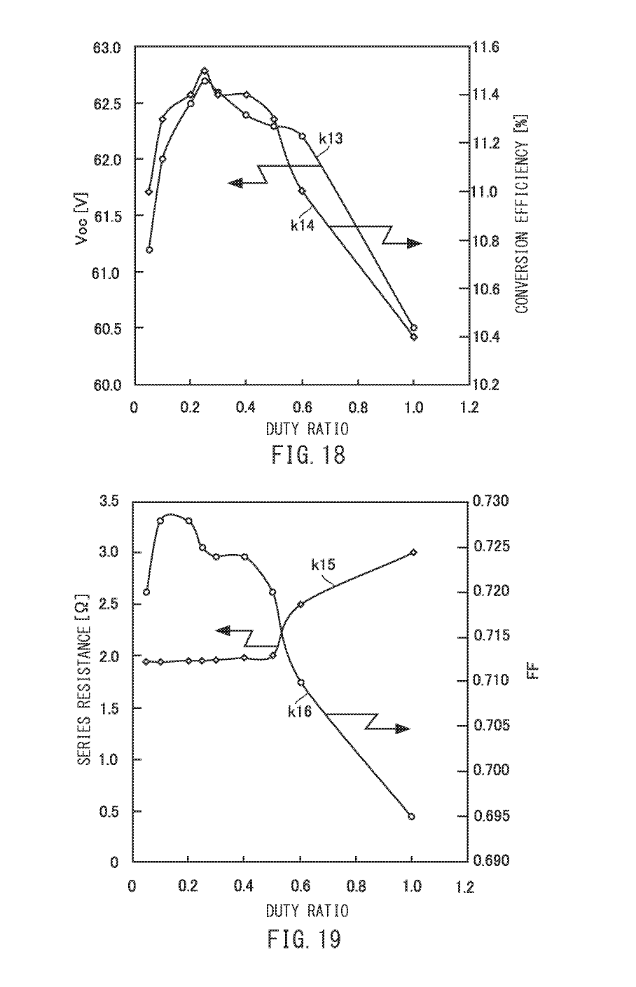

FIG. 18 is a drawing showing the duty ratio dependency of the open-circuit voltage Voc and the conversion efficiency. FIG. 19 is a drawing showing the duty ratio dependency of the series resistance and the fill factor FF.

In FIG. 18, the vertical axis indicates the open-circuit voltage Voc and the conversion efficiency, and the horizontal axis indicates the duty ratio. The curve k13 indicates the duty ratio dependency of the open-circuit voltage Voc, and the curve k14 indicates the duty ratio dependency of the conversion efficiency.

In FIG. 19, the vertical axis indicates the series resistance and the fill factor FF, and the horizontal axis indicates the duty ratio. The curve k15 indicates the duty ratio dependency of the series resistance, and the curve k16 indicates the duty ratio dependency of the fill factor FF.

The fill factor FF is held at a value of 0.720 or more with a duty ratio up to 0.5, and sharply decreases when the duty ratio exceeds 0.5 (refer to curve k16). This is because when the duty ratio exceeds 0.5, the introduction depth of nitrogen atoms due to the plasma processing employing N₂ gas becomes too deep, and the series resistance sharply increases (refer to curve k15).

The open-circuit voltage Voc is held at a value of 62 V or more with the duty ratio in a range of 0.1 to 0.6, and sharply decreases with the duty ratio in a range of less than 0.1 and a range of greater than 0.6 (refer to curve k13). With the duty ratio at less than 0.1, the improvement effect of the open-circuit voltage Voc is not obtained by the introduction of nitrogen atoms due to the plasma processing employing N₂ gas being excessively deep. In a range in which the duty ratio exceeds 0.6, it is thought that the open-circuit voltage Voc is greatly reduced because the introduction amount of nitrogen atoms due to plasma processing employing N₂ gas becomes large, a donor level stemming from nitrogen atoms in the p-type silicon thin film 312 of the p-type semiconductor layer 31 is formed, and the p-type dopant concentration in the p-type silicon thin film 312 is practically reduced.

As a result, a conversion efficiency of 11.3% or more is obtained with the duty ratio in a range of 0.1 to 0.5 (refer to curve k14).

Accordingly, it is understood that a range of 0.1 to 0.5 is appropriate for the duty ratio. It is more preferable that the duty ratio be in a range of 0.2 to 0.4. This is because a conversion efficiency of 11.4% or more is obtained.

Because a case in which the duty ratio is 1 indicates that the pulse power is not used, and the fill factor FF is lowered by greatly increasing the series resistance, the conversion efficiency is not improved.

(Plasma Processing Time Dependency)

The plasma processing time dependency of the electrical characteristics (open-circuit voltage Voc, series resistance Rs, short-circuit current Isc, the fill factor FF and the conversion efficiency) are shown in Table 6. The plasma processing time is the processing time using a plasma employing N₂ gas in step (c-5) in FIG. 10.

TABLE 6

| Processing | | | | | Conversion |
|---|---|---|---|---|---|
| time [sec] | Voc[V] | Rs[Ω] | Isc[A] | FF | efficiency [%] |
| 3 | 60.6 | 1.94 | 3.50 | 0.722 | 10.9 |
| 5 | 61.8 | 1.94 | 3.51 | 0.728 | 11.3 |
| 6 | 62.0 | 1.95 | 3.52 | 0.728 | 11.3 |
| 8 | 62.6 | 1.95 | 3.52 | 0.727 | 11.4 |
| 10 | 62.8 | 1.95 | 3.53 | 0.727 | 11.5 |
| 15 | 62.7 | 1.98 | 3.53 | 0.724 | 11.4 |
| 20 | 62.7 | 2.00 | 3.52 | 0.721 | 11.4 |
| 60 | 62.4 | 2.50 | 3.50 | 0.710 | 11.1 |
| 90 | 61.5 | 4.00 | 3.45 | 0.650 | 9.9 |

The results shown in Table 6 are the electrical characteristics when RF power is set to 150 mW/cm², the film deposition pressure is set to 400 Pa, the substrate temperature is set to 160° C., the frequency of the high frequency power RF is set to 11 MHz, the frequency of the low frequency pulse power LP is set to 400 Hz, the duty ratio of the low frequency pulse power LP is set to 0.25, and the plasma processing time is changed to 3, 5, 6, 8, 10, 15, 20, 60, and 90 seconds. The areas of the substrates 121 to 124 is 14000 cm², and the pulse power PP is supplied to four cathode electrodes 133A to 133D from one power supply 140.

As shown in Table 6, a conversion efficiency of 9.9% or more is obtained in a case in which the plasma processing time is changed in a range of 3 sec. to 90 sec.

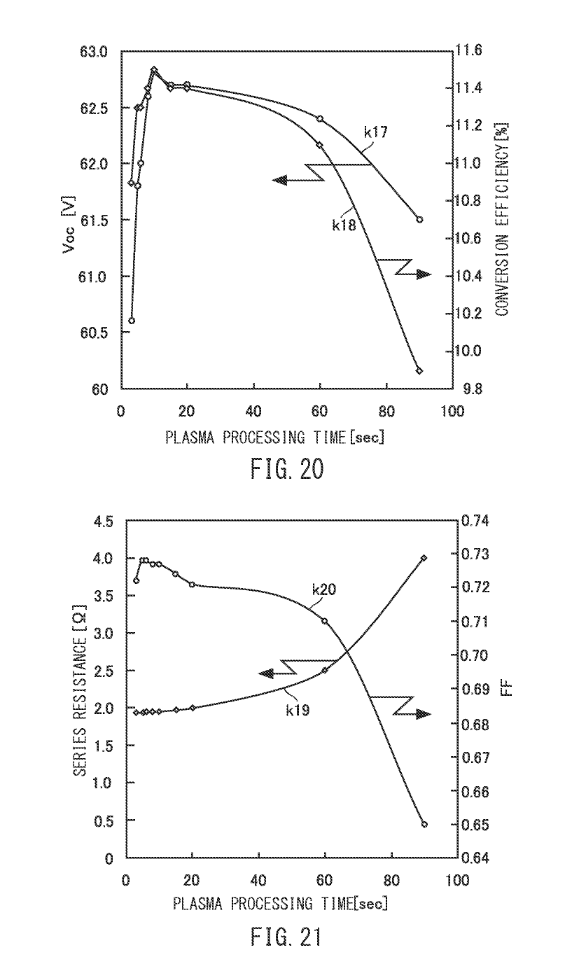

FIG. 20 is a drawing showing the plasma processing time dependency of the open-circuit voltage Voc and the conversion efficiency. FIG. 21 is a drawing showing the plasma processing time dependency of the series resistance and the fill factor FF.

In FIG. 20, the vertical axis indicates the open-circuit voltage Voc and the conversion efficiency, and the horizontal axis indicates the plasma processing time. The curve k17 indicates the plasma processing time dependency of the open-circuit voltage Voc, and the curve k18 indicates the plasma processing time dependency of the conversion efficiency.

In FIG. 21, the vertical axis indicates the series resistance and the fill factor FF, and the horizontal axis indicates the plasma processing time. The curve k19 indicates the plasma processing time dependency of the series resistance, and the curve k20 indicates the plasma processing time dependency of the fill factor FF.

The fill factor FF is held at a value of 0.71 or more with a plasma processing time of up to 60 seconds, and sharply decreases when the plasma processing time exceeds 60 seconds (refer to curve k20). This is because when the plasma processing time exceeds 60 seconds, the nitrogen atom concentration introduced with respect to the p-type silicon thin film 311 becomes excessively high and the series resistance sharply increases (refer to curve k19).

The open-circuit voltage Voc is held at a value of 61.5 V or more with the plasma processing time in a range of 5 seconds to 90 seconds, and greatly decreases because nitrogen atoms are almost completely not introduced with respect to the p-type silicon thin film 311 at a plasma processing time of less than 5 seconds (refer to curve k17).

As a result, a conversion efficiency of 11.1% or more is obtained with plasma processing time in a range of 5 seconds to 60 seconds (refer to curve 18).

Accordingly, it is understood that a range of 5 seconds to 60 seconds is appropriate for the plasma processing time. A range of 6 seconds to 20 seconds is more preferable as the plasma processing time. This is because a conversion efficiency of 11.3% or more is obtained.

As described above, a range of 1 MHz to 50 MHz is appropriate for the frequency of the high frequency power RF, a range of 100 Hz to 1 kHz is appropriate for the frequency of the low frequency pulse power LP, a range of 100 mW/cm² to 300 mW/cm² is appropriate for the density of the high frequency power RF, a range of 300 Pa to 600 Pa is appropriate for the film deposition pressure, a range of 140° C. to 190° C. is appropriate for the substrate temperature, a range of 0.1 to 0.5 is appropriate for the duty ratio of the low frequency pulse power LP, and a range of 5 seconds to 60 seconds is appropriate for the processing time using a plasma employing N₂ gas.

It is possible to increase the in-plane uniformity of the decomposition ratio of the N₂ gas in the plane of the anode electrodes 132A to 132D and the cathode electrodes 133A to 133D by setting the density of the high frequency power RF to a range of 100 mW/cm² to 300 mW/cm², and setting the film deposition pressure to a range of 300 Pa to 600 Pa. As a result, in a case in which the p-type silicon thin film or the n-type silicon thin film are processed by a plasma employing N₂ gas, the nitrogen atoms are uniformly included in the entire plane of the photovoltaic device, it is possible to realize a p-type semiconductor layer or an n-type semiconductor layer having an optimal nitrogen content for obtaining an effect of improving the open-circuit voltage without the series resistance being increased, and it is possible to improve the conversion efficiency in a large area photovoltaic device.

The plasma damage that plasma processing employing N₂ gas imparts on the p-type silicon thin film or the n-type silicon thin film is reduced by setting the film deposition pressure to 300 Pa to 600 Pa, and it is possible to form a high quality p-type semiconductor layer or an n-type semiconductor layer in which the defected density is reduced, as a result.

By setting the substrate temperature to 140° C. to 190° C., it is possible to increase the hydrogen concentration in the film of a p-type semiconductor layer (or n-type semiconductor layer) formed using the first step of depositing a p-type silicon thin film (or n-type silicon thin film), the second step of irradiating the p-type silicon thin film (or n-type silicon thin film) thus deposited with a plasma employing N₂ gas, and the third step of depositing a p-type silicon thin film (or n-type silicon thin film) on the p-type silicon thin film (or n-type silicon thin film) thus irradiated with plasma, and possible obtain a high open-circuit voltage as a result.

By setting the frequency of the low frequency pulse power LP to 100 Hz to 1 kHz, it is possible to obtain a stable discharge state in the entire plane of the photovoltaic device, and possible to increase the in-plane uniformity of the decomposition ratio of the N₂ gas in the plane of the anode electrodes 132A to 132D and the cathode electrodes 133A to 133D.

Accordingly, in the plasma processing employing N₂ gas, the density of the high frequency power RF may be in a range of 100 mW/cm² to 300 mW/cm², the film deposition pressure in a range of 300 Pa to 600 Pa, the frequency of the high frequency power RF in a range of 1 MHz to 50 MHz, the frequency of the low frequency pulse power LP in a range of 100 Hz to 1 kHz, and the substrate temperature in a range of 140° C. to 190° C.

A more preferable frequency for the high frequency power RF is 9 MHz to 14 MHz. A more preferable density for the high frequency power RF is 150 mW/cm² to 200 mW/cm². As shown in Table 2, it is possible to improve the open-circuit voltage Voc up to 62.8 v to 62.9 V by suppressing the series resistance Rs to 1.97Ω to 1.98Ω, and, as a result, a maximum conversion efficiency of 11.5% is obtained.

A more preferable film deposition pressure is 350 Pa to 450 Pa. As shown in FIGS. 14 and 15, it is possible to improve the open-circuit voltage Voc to a value higher than 62.5 V by suppressing the series resistance to 1.97Ω, and, as a result, it is possible to maximally improve the conversion efficiency.

A more preferable substrate temperature is 150° C. to 170° C. As shown in FIGS. 16 and 17, it is possible to improve the open-circuit voltage Voc to a value higher than 62 V by suppressing the series resistance to 1.97Ω, and, as a result, it is possible to maximally improve the conversion efficiency.

By setting the duty ratio of the low frequency pulse power LP in the plasma processing employing N₂ gas to 0.1 to 0.5, it is possible to restrict the energy of nitrogen radical occurring through the N₂ gas decomposing. As a result, the depth to which nitrogen is introduced with respect to the p-type silicon thin film (or n-type silicon thin film) is restricted to the surface region, and it is possible to improve the uniformity of the depth of nitrogen introduction in the plane of the photovoltaic device. Accordingly, an increase in the series resistance due to the nitrogen introduction is suppressed, and it is possible to achieve an excellent fill factor FF value in the entire plane of the photovoltaic device.

Thereby, the duty ratio of the low frequency pulse power LP in the plasma processing employing N₂ gas is preferably 0.1 to 0.5. The duty ratio of the low frequency pulse power LP is more preferably 0.2 to 0.3. This is because a fill factor FF of 0.724 to 0.728 is obtained by suppressing the series resistance Rs to 1.95 to 1.96Ω (refer to Table 5).

By setting the processing time of the plasma processing employing N₂ gas to 5 seconds to 60 seconds, the nitrogen concentration introduced with respect to the p-type silicon thin film (or n-type silicon thin film) is suppressed from becoming too high, and is possible to achieve an excellent fill factor FF value in the entire plane of the photovoltaic device.

A range of 5 seconds to 60 seconds is preferable as the processing time of the plasma processing employing N₂ gas. A range of 6 seconds to 20 seconds is preferable as the processing time of the plasma processing employing N₂ gas. This is because a fill factor FF of 0.721 to 0.728 is obtained by suppressing the series resistance Rs to 2.0Ω or less (refer to Table 6).

Because the time necessary for plasma processing is reduced by executing a first step of depositing a p-type silicon thin film (or n-type silicon thin film), a second step of irradiating the p-type silicon thin film (or n-type silicon thin film) thus deposited with plasma employing N₂ gas, and a third step of depositing a p-type silicon thin film (or n-type silicon thin film) on the p-type silicon thin film (or n-type silicon thin film) thus irradiated with plasma in the same chamber, it is possible to shorten the time necessary to manufacture one photovoltaic device. As a result, it is possible to increase the number of photovoltaic devices processed able to be manufactured with one plasma device, and to improve the production efficiency.

Accordingly, the first to third steps are preferably executed in the same chamber (same processing chamber).

By executing the first step of depositing a p-type silicon thin film (or n-type silicon thin film), the second step of irradiating the p-type silicon thin film (or n-type silicon thin film) thus deposited with plasma employing N₂ gas, and the third step of depositing a p-type silicon thin film (or n-type silicon thin film) on the p-type silicon thin film (or n-type silicon thin film) thus irradiated with plasma at the same processing pressure, it is possible to eliminate the time necessary to change the pressure and shorten the time necessary to manufacture one photovoltaic device. As a result, it is possible to increase the number of photovoltaic devices processed able to be manufactured with one plasma device, and to improve the production efficiency.

Accordingly, the first to third steps are executed at the same processing pressure.

By making the layer processed by plasma employing N₂ gas a microcrystalline silicon, it is possible to reduce the series resistance of the photovoltaic device, and possible to obtain an excellent fill factor FF.

Accordingly, the layer processed by plasma employing N₂ gas is preferably a microcrystalline silicon.

Since the conductive layer that includes a nitrogen-containing layer formed by applying the plasma processing employing N₂ gas has a large optical band gap, the open-circuit voltage Voc is improved by suppressing recombination of the photo carrier in the vicinity of the i-type semiconductor layer that contacts the conductive layer. In the photovoltaic device in which the light incident side is a p-type conductive layer, because the p-type conductive layer has a higher photo carrier number greater than the n-type conductive layer, the effect of suppressing the recombination loss by widening the band gap increased more for the p-type conductive layer than the n-type conductive layer. As a result, by applying the plasma processing employing N₂ gas with respect to the p-type conductive layer, it is possible to obtain an improvement effect of a larger open-circuit voltage Voc.

Accordingly, it is preferable that the p-type semiconductor layer be deposited by applying the plasma processing employing N₂ gas.

In a case in which the p-type semiconductor layer that contacts the i-type semiconductor layer formed from microcrystalline silicon includes a nitrogen-containing layer, the fill factor FF is improved over a case in which the p-type semiconductor layer that contacts the i-type semiconductor layer formed from amorphous silicon includes a nitrogen-containing layer. More specifically, since the bonding of the i-type semiconductor layer formed from microcrystalline silicon and the p-type semiconductor layer including a nitrogen-containing layer has less of a mismatch in band gap than the bonding of the i-type semiconductor layer formed from amorphous silicon and a p-type semiconductor layer including a nitrogen-containing layer, and the recombination of the photo carrier is suppressed, the fill factor FF is improved.

Accordingly, it is preferable that the i-type semiconductor layer formed from microcrystalline silicon be deposited after the p-type semiconductor layer including a nitrogen-containing layer is deposited.

By forming all of the p-type semiconductor layer, the i-type semiconductor layer and the n-type semiconductor layer in the same chamber, the time for transporting the photovoltaic device to different chambers is unnecessary, and it is possible to shorten the time necessary to manufacture one photovoltaic device. As a result, it is possible to increase the number of photovoltaic devices processed able to be manufactured with one plasma device, and to improve the production efficiency.

Accordingly, it is preferable that the pin structure which the p-type semiconductor layer including a nitrogen-containing layer, the i-type semiconductor layer and the n-type semiconductor layer are successively stacked be manufactured in the same processing chamber (chamber).

By setting the size of the anode electrode and the cathode electrode to which the plasma excitation power is supplied to 1 m² to 3 m², it is possible to obtain a photovoltaic device with a large generated power, and further possible to increase the production volume of the photovoltaic devices using one plasma device, since the generated power of the photovoltaic device manufactured with one plasma processing is large.

There is an increase in the electrode size, and the in-plane uniformity of the decomposition ratio of the N₂ gas is lowered, thereby becoming difficult for the conversion efficiency to be improved in the entire plane of the photovoltaic device. In order to ensure in-plane uniformity in a large area electrode, it is preferable that the density of the high frequency power RF be in a range of 100 mW/cm² to 300 mW/cm², the film deposition pressure in a range of 300 Pa to 600 Pa, the frequency of the high frequency power RF in a range of 1 MHz to 50 MHz, the frequency of the low frequency pulse power LP in a range of 100 Hz to 1 kHz, the substrate temperature in a range of 140° C. to 190° C., the duty ratio of the low frequency pulse power LP in a range of 0.1 to 0.5, and the processing time of the plasma processing employing N₂ gas in a range of 6 seconds to 60 seconds.

Since one power source supplies the plasma excitation power with respect to the plurality of anode electrodes-cathode electrodes, it is possible to reduce the cost of the plasma device for manufacturing a plurality of photovoltaic device.

Accordingly, it is preferable that the plasma excitation power be supplied by one power supply to the plurality of anode electrode and cathode electrode pairs.

By using the pulse power PP in which a 100 Hz to 1 kHz low frequency pulse power LP is superimposed on the 1 MHz to 50 MHz high frequency power RF in the case of a plasma device that supplies the plasma excitation power by branching multiple stages, it is possible to suppress imbalances in the power between stages, and possible to improve the equality in the conversion efficiency of the plurality of the photovoltaic devices manufactured with one processing chamber.

Above, although the plasma processing employing N₂ gas is performed with respect to the p-type semiconductor layer 31 of the photovoltaic layer 3 of the photovoltaic layers 5 and 3 that configure the solar battery module 40, in Embodiment 1, the plasma processing employing N₂ gas may be performed with respect to the p-type semiconductor layer 51 of the photovoltaic layer 5, the plasma processing employing N₂ gas may be performed with respect to the n-type semiconductor layer 33 of the photovoltaic layer 3, the plasma processing employing N₂ gas may be performed with respect to the n-type semiconductor layer 53 of the photovoltaic layer 5, the plasma processing employing N₂ gas may be performed with respect to the p-type semiconductor layer 31 and the n-type semiconductor layer 33 of the photovoltaic layer 3, or the plasma processing employing N₂ gas may be performed with respect to the p-type semiconductor layer 51 and the n-type semiconductor layer 53 of the photovoltaic layer 5, without being limited thereto. That is, in Embodiment 1, the plasma processing employing N₂ gas may be performed with respect to at least one of the p-type semiconductor layer 31 of photovoltaic layers 3 and 5, the n-type semiconductor layer 33, the p-type semiconductor layer 51 and the n-type semiconductor layer 53.

If the plasma processing employing N₂ gas is performed with respect to at least one of the p-type semiconductor layer 31, the n-type semiconductor layer 33, the p-type semiconductor layer 51 and the n-type semiconductor layer 53, it is possible to improve the open-circuit voltage Voc by suppressing the series resistance.

In a case of performing the plasma processing employing N₂ gas with respect to at least one of the p-type semiconductor layer 31, the n-type semiconductor layer 33, the p-type semiconductor layer 51, and the n-type semiconductor layer 53, the solar battery module 40 is manufactured using the steps (a) to (h) shown in FIGS. 8 and 9, and the steps (c-1) to (c-9) shown in FIGS. 10 and 11.

For example, in a case of performing the plasma processing employing N₂ gas with respect to the n-type semiconductor layer 33, the plasma processing employing N₂ gas is performed with respect to the n-type silicon thin film in the step (c-9) shown in FIG. 11. A case of subjecting the p-type semiconductor layer 51 or like to plasma processing employing the N₂ gas is also the same. The high frequency power, the film deposition pressure, the substrate temperature, the duty ratio of the low frequency pulse power LP, and the plasma processing time employing N₂ gas are set to the values of the appropriate ranges described above.

Although description above was made of a solar battery module 40 manufactured using the plasma device 100A shown in FIG. 6, in Embodiment 1, the solar battery module 40 may be manufactured using the plasma device 100 shown in FIG. 5, without being limited thereto. In a case of manufacturing the solar battery module 40 using the plasma device 100, the photovoltaic layer 43 of the solar battery module 40 is formed in one chamber 101, and thus it is possible to eliminate the time for transporting the sample, and improve the production volume of the solar battery module 40, compared to a case of forming the two photovoltaic layers 5 and 3 that configure the photovoltaic layer 43 in separate chambers.

Although description was made above of performing the plasma processing using N₂ gas, in the embodiments of the invention, the plasma processing may be performed using NH₃ gas, or, in general, the plasma processing may be performed using a raw material including nitrogen atoms, without being limited thereto.

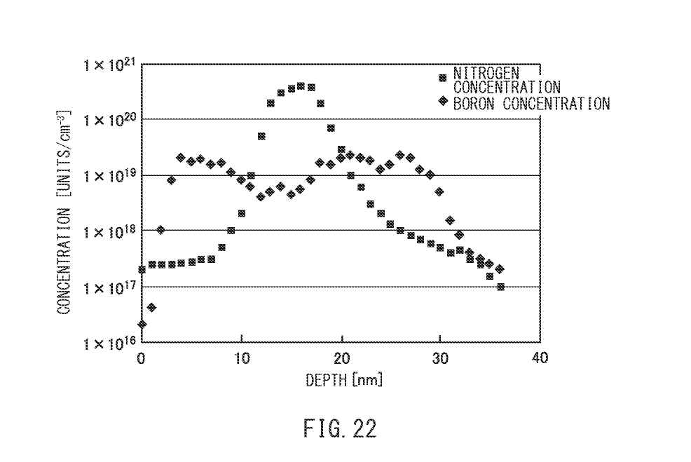

FIG. 22 is a diagram showing the distribution in the depth direction of the nitrogen concentration and the boron concentration. In FIG. 22, the vertical axis represents the concentration, and the horizontal axis represents the depth. The black squares indicate the distribution of the nitrogen concentration in the depth direction, and the black triangles indicate the distribution of the boron concentration in the depth direction.

The distribution of the nitrogen concentration and the boron concentration in the depth direction for the photovoltaic device according to Embodiment 1 obtained as above is measured using a secondary ion mass spectrometry (SIMS) method. After the substrate 1, the transparent conductive film 2, and the photovoltaic layer 5 are removed from the substrate side by a milling process, a SIMS analysis is performed on the photovoltaic device with the structure shown in FIG. 2 as a measurement sample in the depth direction from the p-type semiconductor layer 31 toward the direction of the rear electrode 4.

Accordingly, the 0 nm point in the depth direction of the horizontal axis indicates the interface between the p-type semiconductor layer 31 and the n-type semiconductor layer 53. The measurement results are shown in FIG. 22 as the obtained boron concentration distribution and the nitrogen concentration distribution. It is understood that the nitrogen concentration is lower than 5×10¹⁸ (units/cm⁻³), and the p-type silicon thin film 312 containing a high concentration of nitrogen of 1×10¹⁹ (units/cm⁻³) or more is interposed by the p-type silicon thin films 311 and 313 to which nitrogen is substantially not added.

### Embodiment 2

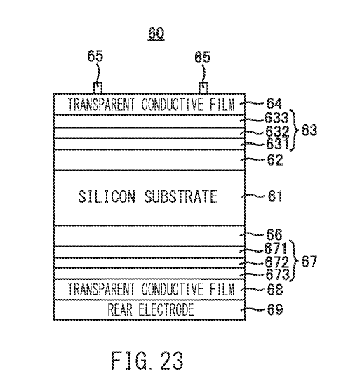

FIG. 23 is a cross-sectional view showing a configuration of a photovoltaic device according to Embodiment 2. With reference to FIG. 23, the photovoltaic device 60 according to Embodiment 2 includes a silicon substrate 61, i-type semiconductor layers 62 and 66, a p-type semiconductor layer 63, transparent conductive films 64 and 68, a grid electrode 65, an n-type semiconductor layer 67, and a rear electrode 69.

The silicon substrate 61 is formed from a single crystal silicon substrate or a polycrystalline silicon substrate. The silicon substrate 61 has a, for example, a thickness of 100 μm to 300 μm, and preferably as a thickness of 100 μm to 200 μm. The silicon substrate 61 has, for example, a (100) plane orientation in a case of being formed from a single crystal silicon substrate. The silicon substrate 61 has a specific resistance of 1.0 Ω·cm to 10 Ω·cm.

The i-type semiconductor layer 62 is arranged in contact with one surface of the silicon substrate 61. The p-type semiconductor layer 63 is arranged in contact with the i-type semiconductor layer 62. The p-type semiconductor layer 63 is formed from a p-type silicon thin films 631 to 633. The p-type silicon thin film 631 is arranged in contact with the i-type semiconductor layer 62, the p-type silicon thin film 632 is interposed in the thickness direction between the p-type silicon thin films 631 and 633, and the p-type silicon thin film 633 is arranged in contact with the transparent conductive film 64.

The transparent conductive film 64 is arranged in contact with the p-type silicon thin film 633 of the p-type semiconductor layer 63. The grid electrode 65 has a comb-like planar shape, and is arranged in contact with the transparent conductive film 64.

The i-type semiconductor layer 66 is arranged in contact with the other main surface of the silicon substrate 61. The n-type semiconductor layer 67 is arranged in contact with the i-type semiconductor layer 66. The n-type semiconductor layer 67 is formed from n-type silicon thin films 671 to 673. The n-type silicon thin film 671 is arranged in contact with the i-type semiconductor layer 66, the n-type silicon thin film 672 is interposed in the thickness direction between the n-type silicon thin films 671 and 673, and the n-type silicon thin film 673 is arranged in contact with the transparent conductive film 68.

The transparent conductive film 68 is formed in contact with the n-type silicon thin film 673 of the n-type semiconductor layer 67. The rear electrode 69 is arranged in contact with the transparent conductive film 68.

The i-type semiconductor layer 62 is formed from an i-type silicon-based semiconductor layer having an amorphous phase or a microcrystalline phase, and more specifically formed from an i-type a-SiC, an i-type a-SiN, an i-type a-Si, an i-type a-SiGe, an i-type a-Ge, an i-type μc-SiC, an i-type μc-SiN, an i-type μc-Si, an i-type μc-SiGe, and an i-type μc-Ge or the like. The i-type semiconductor layer 62 has a film thickness of, for example, 5 to 30 nm.

The p-type semiconductor layer 63 is formed from a p-type silicon-based semiconductor layer having an amorphous phase or a microcrystalline phase, and more specifically, formed from a p-type a-SiC, a p-type a-SiN, a p-type a-Si, a p-type a-SiGe, a p-type μc-SiC, a p-type μc-SiN, a p-type μc-Si, and a p-type μc-SiGe or the like. The p-type semiconductor layer 63 has a film thickness of, for example, 5 to 30 nm.

Each of the p-type silicon thin films 631 and 633 is formed from any one of a p-type a-SiC, a p-type a-SiN, a p-type a-Si, a p-type a-SiGe, a p-type μc-SiC, a p-type μc-SiN, a p-type μc-Si, and a p-type μc-SiGe.

The p-type silicon thin films 632 is formed from any one of a p-type a-SiC, a p-type a-SiN, a p-type a-Si, a p-type a-SiGe, a p-type μc-SiC, a p-type μc-SiN, a p-type μc-Si, and a p-type μc-SiGe to which nitrogen atoms are added. In a case in which the p-type silicon thin film 632 is formed from the same p-type a-SiN or a p-type μc-SiN as the p-type silicon thin films 631 and 633, the nitrogen concentration of the p-type silicon thin film 632 is higher than the nitrogen concentration of the p-type silicon thin films 631 and 633.

Thus, the p-type semiconductor layer 63 has a structure in which a layer including nitrogen atoms is interposed in the thickness direction between layers not containing nitrogen atoms or a structure in which a layer that has a first nitrogen atom concentration is interposed in the thickness direction between layers that have a second nitrogen atom concentration lower than the first nitrogen atom concentration.

The transparent conductive film 64 is formed from ITO, SnO₂, ZnO, or the like. The grid electrode 65 is formed from, for example, Ag.

The i-type semiconductor layer 66 is formed from the same material as the i-type semiconductor layer 62. The i-type semiconductor layer 66 has a film thickness of, for example, 5 to 30 nm.

The n-type semiconductor layer 67 is formed from an n-type silicon-based semiconductor layer having an amorphous phase or a microcrystalline phase, and more specifically formed from an n-type a-SiC, an n-type a-SiN, an n-type a-Si, an n-type a-SiGe, an n-type μc-SiC, an n-type μc-SiN, an n-type μc-Si, and an n-type μc-SiGe or the like. The n-type semiconductor layer 67 has a film thickness of, for example, 5 to 30 nm.

Each of the n-type silicon thin films 671 and 673 is formed from any of an n-type a-SiC, an n-type a-SiN, an n-type a-Si, an n-type a-SiGe, an n-type μc-SiC, an n-type μc-SiN, an n-type μc-Si, and an n-type μc-SiGe.

The n-type silicon thin film 672 is formed from any of an n-type a-SiC, an n-type a-SiN, an n-type a-Si, an n-type a-SiGe, an n-type μc-SiC, an n-type μc-SiN, an n-type μc-Si, and an n-type μc-SiGe to which nitrogen atoms are added. In a case in which the n-type silicon thin film 672 is formed from the same n-type a-SiN or a p-type μc-SiN as the n-type silicon thin film 671 and 673, the nitrogen concentration of the n-type silicon thin film 672 is higher than the nitrogen concentration of the n-type silicon thin films 671 and 673.

Thus, the n-type semiconductor layer 67 has a structure in which a layer including nitrogen atoms is interposed in the thickness direction between layers not including nitrogen atoms or a structure in which a layer that has a first nitrogen atom concentration is interposed in the thickness direction between layers that have a second nitrogen atom concentration lower than the first nitrogen atom concentration.

The transparent conductive film 68 is formed from ITO, SnO₂, ZnO, or the like. The rear electrode 69 is formed from, for example, Ag.

The p-type semiconductor layer 63 and the n-type semiconductor layer 67 may be formed from the same silicon-based semiconductor layer as the i-type semiconductor layers 62 and 66, or may be formed from a silicon-based semiconductor layer different from the i-type semiconductor layers 62 and 66.

Each of i-type semiconductor layers 62 and 66, the p-type semiconductor layer 63 and the n-type semiconductor layer 67 may be formed with a single layer structure or may be formed with a multi-layer structure. In a case in which each of the i-type semiconductor layers 62 and 66, the p-type semiconductor layer 63 and the n-type semiconductor layer 67 are formed with a multi-layer structure, the plurality of layers may be alternately formed from the same silicon-based semiconductor layers, or may be alternately formed from different silicon-based semiconductor layers.

In the photovoltaic device 60, solar light is incident on the photovoltaic device 60 from the grid electrode 65 side. The i-type semiconductor layer 62 and the p-type semiconductor layer 63 are referred to as “light receiving surface side bonding layers” and the i-type semiconductor layer 66 and the n-type semiconductor layer 67 are referred to as “back side bonding layers”.

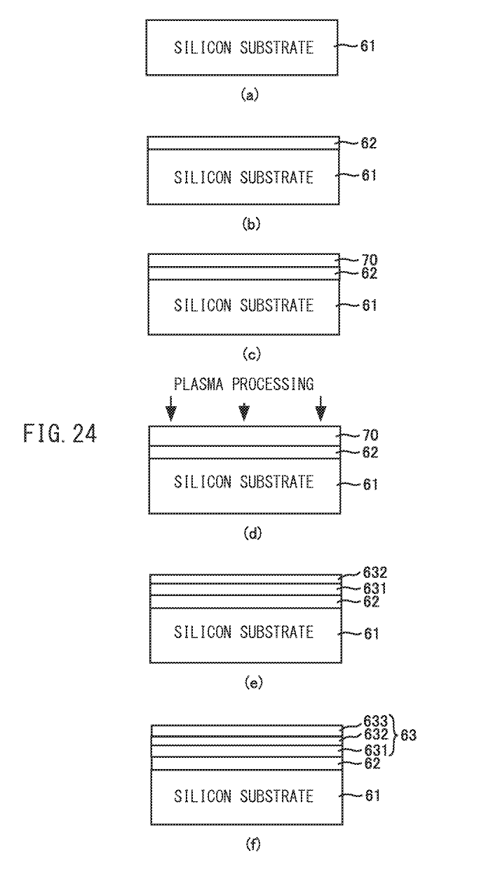

The method for manufacturing the photovoltaic device 60 will be described. FIGS. 24 to 26 are first to third process drawings, respectively, for describing the method of manufacturing the photovoltaic device 60 shown in FIG. 23.

In FIGS. 24 to 26, a method for manufacturing the photovoltaic device 60 is described using a case in which the silicon substrate 61 is formed from an n-type single crystal silicon substrate, the i-type semiconductor layers 62 and 66 are formed from an i-type a-Si, the p-type semiconductor layer 63 is formed from a p-type μc-Si, the n-type semiconductor layer 67 is formed from an n-type μc-Si, and the transparent conductive films 64 and 68 are formed from ITO as an example.

When the manufacturing of the photovoltaic device 60 is started, the n-type single crystal silicon substrate is degreased by ultrasonic cleaning with ethanol or the like, and thereafter, the natural oxide film formed on the surface of the n-type single crystal silicon substrate by immersion of the n-type single crystal silicon substrate in hydrofluoric acid is removed, and the surface of the n-type silicon substrate is terminated with hydrogen.

In a case of texturing the surface of the n-type single crystal silicon substrate, after the n-type single crystal silicon substrate is ultrasonically cleaned with ethanol or the like, the surface of the n-type single crystal silicon substrate is chemically anisotropically etched using an alkali, thereby texturing the surface of the n-type single crystal silicon substrate. Thereafter, the natural oxide film is removed using hydrofluoric acid as described above, and the surface of the n-type single crystal silicon substrate is terminated with hydrogen. Thereby, the silicon substrate 61 is prepared (refer to step (a) in FIG. 24).

The silicon substrate 61 is installed on the anode electrode 102 of the plasma device 100 as a substrate 120.

The flow amounts of the raw material gas for forming the i-type semiconductor layers 62 and 66, the p-type semiconductor layer 63 and the n-type semiconductor layer 67 are shown in Table 7.

TABLE 7

| | SiH₄ | H₂ | B₂H₆/H₂ | PH₃/H₂ | N₂ |
|---|---|---|---|---|---|
| | (sccm) | (sccm) | (sccm) | (sccm) | (sccm) |
| i-type semicon- | 10 | 100 | — | — | — |
| ductor layer 62 | | | | | |
| p-type silicon | 2 | 120 | 12 | — | — |
| thin film 70 | | | | | |
| Plasma | — | — | — | — | Flow rate when |
| processing | | | | | N₂/SiH₄ flow |
| | | | | | rate ratio is 5% |
| p-type silicon | 2 | 120 | 12 | — | — |
| thin film 633 | | | | | |
| i-type semicon- | 10 | 100 | — | — | — |
| ductor layer 66 | | | | | |
| n-type silicon | 4 | 250 | — | 25 | — |
| thin film 71 | | | | | |
| Plasma | — | — | — | — | Flow rate when |
| processing | | | | | N₂/SiH₄ flow |
| | | | | | rate ratio is 5% |
| n-type silicon | 4 | 250 | — | 25 | — |
| thin film 673 | | | | | |

The gas supply device 105 supplies 10 sccm of SiH₄ gas and 100 sccm of H₂ gas to the interior of the cathode electrode 103 via the supply pipe 104. As a result, the SiH₄ gas and the H₂ gas is supplied to the region between the anode electrode 102 and the cathode electrode 103.

The pressure inside the chamber 101 is set to 400 Pa to 1000 Pa using the gate valve 107. Furthermore, the temperature of the substrate 120 is set to 170° C. to 200° C. using a heater built into the anode electrode 102.

Thereby, the power source 110 applies the pulse power PP to the cathode electrode 103 via the impedance matching circuit 109. In this case, the frequency of the low frequency pulse power LP is, for example, 300 Hz to 500 Hz, and the frequency of the high frequency power RF is, for example, 11 MHz to 14 MHz. The power of the high frequency power in the pulse power PP is, for example, 20 mW/cm² to 500 mW/cm².

Thereby, plasma is generated in the region between the anode electrode 102 and the cathode electrode 103, and the i-type semiconductor layer 62 formed from an i-type a-Si is deposited on one main surface of the silicon substrate 61 (refer to step (b) in FIG. 24).

When the film thickness of the i-type semiconductor layer 62 is 5 nm to 30 nm, the gas supply device 105 reduces the flow rate of the SiH₄ gas from 10 sccm to 2 sccm, increases the flow rate of the H₂ gas from 100 sccm to 120 sccm, and newly supplies 12 sccm of the hydrogen diluted B₂H₆ gas to the interior of the cathode electrode 103 via the supply pipe 104.

Thereby, the p-type silicon thin film 70 formed from a p-type μc-Si is deposited on the i-type semiconductor layer 62 (refer to step (c) in FIG. 24).

When the film thickness of the p-type silicon thin film 70 is the desired value, the gas supply device 105 stops the SiH₄ gas, the H₂ gas, and the B₂H₆ gas, and supplies the N₂ gas at a flow rate ratio of N₂/SiH₄ of 5% to the interior of the cathode electrode 103 via the supply pipes 104. Although a range of 1% to 10% is used as the N₂/SiH₄ flow rate ratio, 5% is used herein.

As a result, the p-type silicon thin film 70 is processed by plasma employing N₂ gas (refer to step (d) in FIG. 24).

As a result, the p-type silicon thin films 631 and 632 are formed (refer to step (e) in FIG. 24). The p-type silicon thin film 631 is formed from a p-type μc-Si not including nitrogen atoms, and the p-type silicon thin film 632 is formed from a p-type μc-Si including nitrogen atoms.

After the step (e), the gas supply device 105 stops the N₂ gas, and supplies 2 sccm of SiH₄ gas, 120 sccm of H₂ gas, 12 sccm of hydrogen diluted B₂H₆ gas to the interior of the cathode electrode 103 via the supply pipe 104.

Thereby, the p-type silicon thin film 633 formed from a p-type μc-Si is deposited on the p-type silicon thin film 632 (refer to step (f) in FIG. 24).

The film thickness of the p-type semiconductor layer 63 formed from the p-type silicon thin films 631 to 633 is, for example, 5 to 30 nm. The overall film thickness of the p-type silicon thin films 631 and 632 is the same as the film thickness of the p-type silicon thin film 70 deposited in step (c). Accordingly, the ratio of the overall film thickness of the p-type silicon thin films 631 and 632 and the film thickness of the p-type silicon thin film 633 is arbitrary.

When the film thickness of the p-type semiconductor layer 63 formed from the p-type silicon thin films 631 to 633 is 5 nm to 30 nm, the gas supply device 105 stops the SiH₄ gas, the H₂ gas, and the B₂H₆ gas. The heater built into the anode electrode 102 is switched off, and the gate valve 107 is fully opened.

When the substrate temperature becomes room temperature, the sample is removed from the plasma device 100, and the sample is cleaned with hydrofluoric acid. Thereby, the rear surfaces of the p-type semiconductor layer 63 and the silicon substrate 61 are terminated with hydrogen.

Thereafter, the sample is installed on the anode electrode 102 so that the rear surface of the silicon substrate 61 faces the cathode electrode 103.

The gas supply device 105 supplies 10 sccm of SiH₄ gas and 100 sccm of H₂ gas to the interior of the cathode electrode 103 via the supply pipe 104. As a result, the SiH₄ gas and the H₂ gas is supplied to the region between the anode electrode 102 and the cathode electrode 103.

The pressure inside the chamber 101 is set to 400 Pa to 1000 Pa using the gate valve 107. The temperature of the sample is set to 170° C. to 200° C. using heaters built into the anode electrode 102.

Thereby, the power source 110 applies the pulse power PP to the cathode electrode 103 via the impedance matching circuit 109. In this case, the frequency of the low frequency pulse power LP is, for example, 300 Hz to 500 Hz, and the frequency of the high frequency power RF is, for example, 11 MHz to 14 MHz. The power of the high frequency power in the pulse power PP is, for example, 20 mW/cm² to 500 mW/cm².

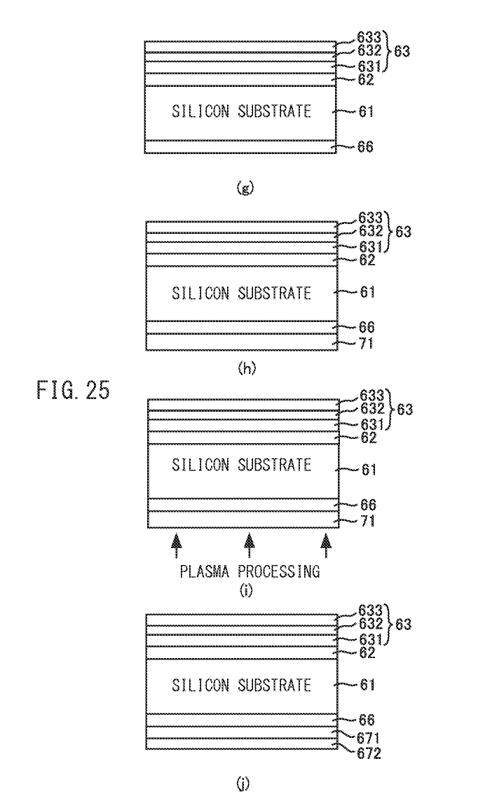

Thereby, plasma is generated in the region between the anode electrode 102 and the cathode electrode 103, and the i-type semiconductor layer 66 formed from an i-type a-Si is deposited on the other main surface (=rear surface) of the silicon substrate 61 (refer to step (g) in FIG. 25).

When the film thickness of the i-type semiconductor layer 66 is 5 nm to 30 nm, the gas supply device 105 reduces the flow rate of the SiH₄ gas from 10 sccm to 4 sccm, increases the flow rate of the H₂ gas from 100 sccm to 250 sccm, and newly supplies 25 sccm of the hydrogen diluted PH₃ gas to the interior of the cathode electrode 103 via the supply pipe 104.

Thereby, the n-type silicon thin film 71 formed from an n-type μc-Si is deposited on the i-type semiconductor layer 66 (refer to step (h) in FIG. 25).

When the film thickness of the n-type silicon thin film 71 is the desired value, the gas supply device 105 stops the SiH₄ gas, the H₂ gas, and the PH₃ gas, and newly supplies the N₂ gas to the interior of the cathode electrode 103 via the supply pipes 104. As a result, the n-type silicon thin film 71 is processed by plasma employing N₂ gas (refer to step (i) in FIG. 25).

As a result, the n-type silicon thin films 671 and 672 are formed (refer to step (j) in FIG. 25). The n-type silicon thin film 671 is formed from n-type μc-Si not including nitrogen atoms, and the n-type silicon thin film 672 is formed from an n-type μc-Si including nitrogen atoms.

After the step (j), the gas supply device 105 stops the N₂ gas, and supplies 4 sccm of SiH₄ gas, 250 sccm of H₂ gas, 25 sccm of hydrogen diluted PH₃ gas to the interior of the cathode electrode 103 via the supply pipe 104.

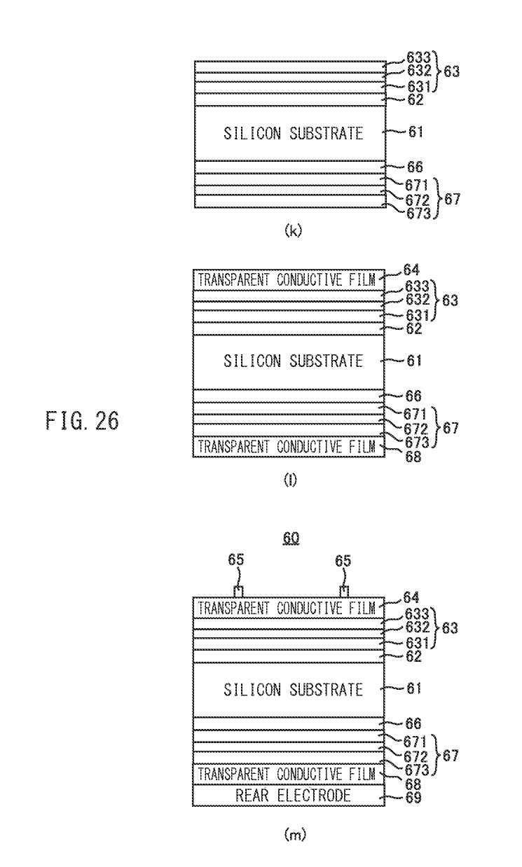

Thereby, the n-type silicon thin film 673 formed from an n-type μc-Si is deposited on the n-type silicon thin film 672 (refer to step (k) in FIG. 26).

The film thickness of the n-type semiconductor layer 67 formed from the n-type silicon thin films 671 to 673 is, for example, 5 to 30 nm. The overall film thickness of the n-type silicon thin films 671 and 672 is the same as the film thickness of the n-type silicon thin film 71 deposited in step (h). Accordingly, the ratio of the overall film thickness of the n-type silicon thin films 671 and 672 and the film thickness of the n-type silicon thin film 673 is arbitrary.

When the film thickness of the n-type semiconductor layer 67 formed from the n-type silicon thin films 671 to 673 is 5 nm to 30 nm, the gas supply device 105 stops the SiH₄ gas, the H₂ gas, and the PH₃ gas. The heater built into the anode electrode 102 is switched off, and the gate valve 107 is fully opened.

When the substrate temperature becomes room temperature, the sample is removed from the plasma device 100, and the removed sample is set on the sputtering device. The transparent conductive films 64 and 68 formed from ITO are formed on the p-type semiconductor layer 63 and the n-type semiconductor layer 67, respectively, using the sputtering device (refer to step (l) in FIG. 26). In this case, the film thickness of the transparent conductive films 64 and 68 is, for example, 50 nm to 150 nm.

Thereafter, the grid electrode 65 and the rear electrode 69 are formed on the transparent conductive films 64 and 68, respectively, through screen printing and firing of Ag. In this case, the film thickness of the grid electrode 65 and the rear electrode 69 is, for example, 50 nm to 200 nm. Thereby, the photovoltaic device 60 is completed (refer to step (m) in FIG. 26).

As described above, the photovoltaic device 60, similarly to Embodiment 1 is manufactured with plasma generated using power PP in which a low frequency pulse power LP is superimposed on a high frequency power RF. As a result, discharge is stable, and it is possible to improve the in-plane uniformity of the nitrogen content in the p-type semiconductor layer 63 and the n-type semiconductor layer 67 in the plane of the photovoltaic device 60.

Accordingly, the open-circuit voltage Voc is improved by suppressing a lowering of the fill factor FF of the photovoltaic device 60. The short-circuit current Isc is improved by improving the transmissivity of the light receiving surface side bonding layer.

Thereby, it is possible to improve the in-plane uniformity of nitrogen content concentration in a large-area photovoltaic device, and to improve the conversion efficiency of the photovoltaic device.

The silicon substrate 61 of the photovoltaic device 60 may be formed from an n-type polycrystalline silicon substrate. In this case, the surface of the light receiving surface side of the silicon substrate 61 is textured by etching. Also in a case in which the silicon substrate 61 is formed from an n-type polycrystalline silicon substrate, the photovoltaic device 60 is manufactured according to the steps (a) to steps (m) shown in FIGS. 24 to 26.

The silicon substrate 61 may be formed from a p-type single crystal silicon substrate or a p-type polycrystalline silicon substrate. In this case, the grid electrode 65 is arranged in contact with the transparent conductive film 68, and the rear electrode 69 is arranged in contact with the transparent conductive film 64. The solar light is incident on the photovoltaic device 60 from the transparent conductive film 68. Also in a case in which the silicon substrate 61 is formed from a p-type single crystal silicon substrate or a p-type polycrystalline silicon substrate, the photovoltaic device 60 is manufactured according to the steps (a) to steps (m) shown in FIGS. 24 to 26.

In the photovoltaic device 60, at least one of the p-type semiconductor layer 63 and the n-type semiconductor layer 67 may be formed from a structure in which the silicon-based semiconductor layer including nitrogen atoms is interposed in the thickness direction between silicon-based semiconductor layers not including nitrogen atoms, or a structure in which a silicon-based semiconductor layer that has a first nitrogen atom concentration is interposed in the thickness direction between silicon-based semiconductor layers that have a second nitrogen atom concentration lower than the first nitrogen atom concentration. This is because it is possible to improve the open-circuit voltage Voc by suppressing a lowering of the fill factor FF if at least one of the p-type semiconductor layer 63 and the n-type semiconductor layer 67 is formed from such a structure.

Furthermore, the photovoltaic device 60 may not include the i-type semiconductor layers 62 and 66. This is because, even without the i-type semiconductor layers 62 and 66, since at least one of the p-type semiconductor layer 63 and the n-type semiconductor layer 67 has a structure in which the silicon-based semiconductor layer including nitrogen atoms is interposed in the thickness direction between silicon-based semiconductor layers not including nitrogen atoms, or a structure in which a silicon-based semiconductor layer that has a first nitrogen atom concentration is interposed in the thickness direction between silicon-based semiconductor layers that have a second nitrogen atom concentration lower than the first nitrogen atom concentration, it is possible to improve the open-circuit voltage Voc by suppressing a lowering of the fill factor FF.

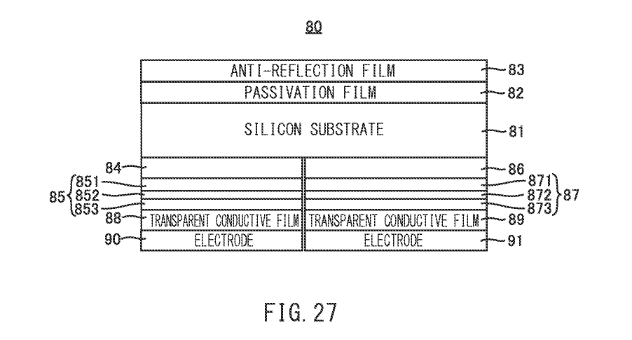

FIG. 27 is a cross-sectional view showing a separate configuration of a photovoltaic device according to Embodiment 2. The photovoltaic device according to Embodiment 2 may be the photovoltaic device 80 shown in FIG. 27.

With reference to FIG. 27, the photovoltaic device 80 includes a silicon substrate 81, a passivation film 82, an anti-reflection film 83, i-type semiconductor layers 84 and 86, an n-type semiconductor layer 85, a p-type semiconductor layer 87, transparent conductive films 88 and 89, and electrodes 90 and 91.

The silicon substrate 81 is formed from an n-type single crystal silicon substrate or an n-type polycrystalline silicon substrate. The silicon substrate 81 has, for example, a thickness of 100 μm to 300 μm, and preferably as a thickness of 100 μm to 200 μm. The silicon substrate 81 has a specific resistance of 1.0 Ω·cm to 10 Ω·cm. The silicon substrate 81 preferably has a (100) plane orientation in a case of being formed from an n-type single crystal silicon substrate.

The passivation film 82 is arranged in contact with one surface of the silicon substrate 81. The anti-reflection film 83 is arranged in contact with the passivation film 82.

The i-type semiconductor layer 84 is arranged in contact with the other surface of the silicon substrate 81. The i-type semiconductor layer 86 neighbors the i-type semiconductor layer 84 in the in plane direction of the silicon substrate 81, and is arranged in contact with the other surface of the silicon substrate 81.

The n-type semiconductor layer 85 is arranged in contact with the i-type semiconductor layer 84. The n-type semiconductor layer 85 is formed from n-type silicon thin films 851 to 853. The n-type silicon thin film 851 is arranged in contact with the i-type semiconductor layer 84, the n-type silicon thin film 852 is interposed in the thickness direction between the n-type silicon thin films 851 and 853, and the n-type silicon thin film 853 is arranged in contact with the transparent conductive film 88.

The p-type semiconductor layer 87 is arranged in contact with the i-type semiconductor layer 86. The p-type semiconductor layer 87 is formed from p-type silicon thin films 871 to 873. The p-type silicon thin film 871 is arranged in contact with the i-type semiconductor layer 86, the p-type silicon thin film 872 is interposed in the thickness direction between the p-type silicon thin films 871 and 873, and the p-type silicon thin film 873 is arranged in contact with the transparent conductive film 89.

The transparent conductive film 88 is formed in contact with the n-type silicon thin film 853 of the n-type semiconductor layer 85. The transparent conductive film 89 is formed in contact with the p-type silicon thin film 873 of the p-type semiconductor layer 87.

The electrode 90 is arranged in contact with the transparent conductive film 88. The electrode 91 is arranged in contact with the transparent conductive film 89.

In the photovoltaic device 80, the n-type semiconductor layer 85 and the p-type semiconductor layer 87 have the same length in the direction perpendicular to the paper surface in FIG. 27. The area occupancy ratio that is the proportion that the area of the entire p-type semiconductor layer 87 occupies in the area of the silicon substrate 81 is 60% to 93%, and the area occupancy ratio that is the proportion that the area of the entire n-type semiconductor layer 85 occupies in the area of the silicon substrate 81 is 5% to 20%.

In this way, increasing the area occupancy ratio of the p-type semiconductor layer 87 to be greater than the area occupancy ratio of the n-type semiconductor layer 85 is in order to easily separate the electrons and the positive holes photoexcited in the silicon substrate 81 by pn junction (p-type semiconductor layer 87/silicon substrate 81 (=n-type single crystal silicon substrate)), and increase the contribution ratio of the generated power of the photoexcited electrons and positive holes.

The passivation film 82 is formed from, for example, silicon oxide (SiO₂), and has a film thickness of 50 nm to 100 nm. The anti-reflection film 83 is formed from, for example, silicon nitride (Si₃N₄), and has a film thickness of 50 nm to 100 nm.

The i-type semiconductor layer 84 is formed from an i-type silicon-based semiconductor layer having an amorphous phase or a microcrystalline phase, and more specifically, formed from an i-type a-SiC, an i-type a-SiN, an i-type a-Si, an i-type a-SiGe, an i-type a-Ge, an i-type μc-SiC, an i-type μc-SiN, an i-type μc-Si, and an i-type μc-SiGe, and an i-type μc-Ge or the like. The i-type semiconductor layer 84 has a film thickness of, for example, 5 nm to 30 nm.

The n-type semiconductor layer 85 is formed from an n-type silicon-based semiconductor layer having an amorphous phase or a microcrystalline phase, and more specifically formed from an n-type a-SiC, an n-type a-SiN, an n-type a-Si, an n-type a-SiGe, an n-type μc-SiC, an n-type μc-SiN, an n-type μc-Si, and an n-type μc-SiGe or the like. The n-type semiconductor layer 85 has a film thickness of, for example, 5 nm to 30 nm.

Each of the n-type silicon thin films 851 and 853 is formed from any of an n-type a-SiC, an n-type a-SiN, an n-type a-Si, an n-type a-SiGe, an n-type μc-SiC, an n-type μc-SiN, an n-type μc-Si, and an n-type μc-SiGe.

The n-type silicon thin film 852 is formed from any of an n-type a-SiC, an n-type a-SiN, an n-type a-Si, an n-type a-SiGe, an n-type μc-SiC, an n-type μc-SiN, an n-type μc-Si, and an n-type μc-SiGe to which nitrogen atoms are added. In a case in which the n-type silicon thin film 852 is formed from the same n-type a-SiN or n-type μc-SiN as the n-type silicon thin films 853 and 851, the nitrogen concentration of the n-type silicon thin film 852 is higher than the nitrogen concentration of the n-type silicon thin films 851 and 853.

Thus, the n-type semiconductor layer 85 has a structure in which a layer including nitrogen atoms is interposed in the thickness direction between layers not including nitrogen atoms or a structure in which a layer that has a first nitrogen atom concentration is interposed in the thickness direction between layers that have a second nitrogen atom concentration lower than the first nitrogen atom concentration.

The i-type semiconductor layer 86 is formed from the same material as the i-type semiconductor layer 84. The i-type semiconductor layer 86 has a film thickness of, for example, 5 nm to 30 nm.

The p-type semiconductor layer 87 is formed from a p-type silicon-based semiconductor layer having an amorphous phase or a microcrystalline phase, and more specifically, formed from a p-type a-SiC, a p-type a-SiN, a p-type a-Si, a p-type a-SiGe, a p-type μc-SiC, a p-type μc-SiN, a p-type μc-Si, and a p-type μc-SiGe or the like. The p-type semiconductor layer 87 has a film thickness of, for example, 5 nm to 30 nm.

Each of the p-type silicon thin films 871 and 873 is formed from any one of a p-type a-SiC, a p-type a-SiN, a p-type a-Si, a p-type a-SiGe, a p-type μc-SiC, a p-type μc-SiN, a p-type μc-Si, and a p-type μc-SiGe.

The p-type silicon thin films 872 is formed from any one of a p-type a-SiC, a p-type a-SiN, a p-type a-Si, a p-type a-SiGe, a p-type μc-SiC, a p-type μc-SiN, a p-type μc-Si, and a p-type μc-SiGe to which nitrogen atoms are added. In a case in which the p-type silicon thin film 872 is formed from the same p-type a-SiN or a p-type μc-SiN as the p-type silicon thin films 871 and 873, the nitrogen concentration of the p-type silicon thin film 872 is higher than the nitrogen concentration of the p-type silicon thin films 871 and 873.

In this way, the p-type semiconductor layer 87 has a structured in which a layer including nitrogen atoms is interposed in the thickness direction between layers not including nitrogen atoms or a structure in which a layer that has a first nitrogen atom concentration is interposed in the thickness direction between layers that have a second nitrogen atom concentration lower than the first nitrogen atom concentration.

Each of the transparent conductive films 88 and 89 is formed from ITO, SnO₂, ZnO, or the like. The electrodes 90 and 91 are each formed from, for example, Ag.

The n-type semiconductor layer 85 and the p-type semiconductor layer 87 may be formed from the same silicon-based semiconductor layers as the i-type semiconductor layers 84 and 86, or may be formed from silicon-based semiconductor layers different from the i-type semiconductor layers 84 and 86.

Each of i-type semiconductor layers 84 and 86, the n-type semiconductor layer 85, and the p-type semiconductor layer 87 may be formed with a single layer structure or may be formed with a multi-layer structure. In a case in which each of the i-type semiconductor layers 84 and 86, the n-type semiconductor layer 85, and the p-type semiconductor layer 87 are formed with a multi-layer structure, the plurality of layers may be alternately formed from the same silicon-based semiconductor layers, or may be alternately formed from different silicon-based semiconductor layers.

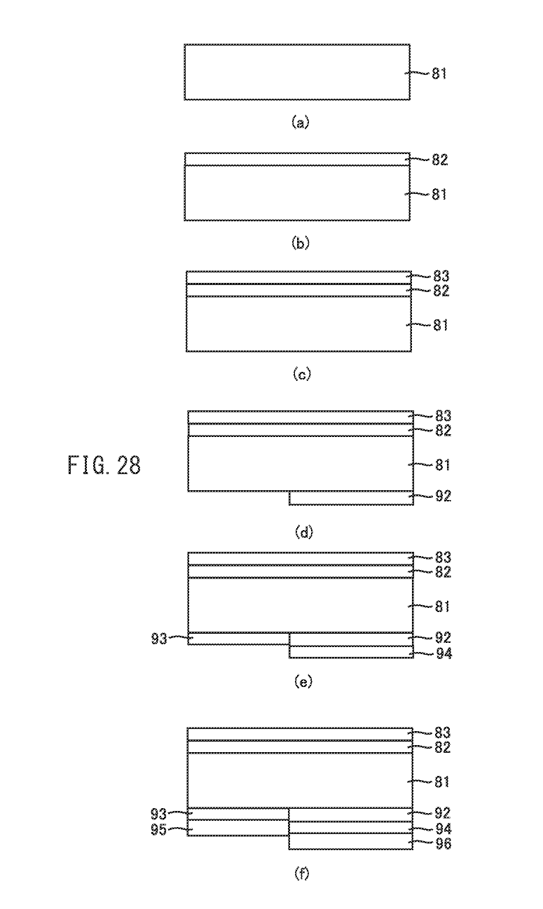

The method for manufacturing the photovoltaic device 80 will be described. FIGS. 28 to 32 are first to fifth process drawings, respectively, for describing the method of manufacturing the photovoltaic device 80 shown in FIG. 27.

In FIGS. 28 to 32, a method for manufacturing the photovoltaic device 80 is described using a case in which the silicon substrate 81 is formed from an n-type single crystal silicon substrate, the i-type semiconductor layers 84 and 86 are formed from an i-type a-Si, the n-type semiconductor layer 85 is formed from a p-type μc-Si, the p-type semiconductor layer 87 is formed from an n-type μc-Si, and the transparent conductive films 88 and 89 are formed from ZnO as an example.

When the manufacturing of the photovoltaic device 80 is started, the n-type single crystal silicon substrate is degreased by ultrasonic cleaning with ethanol or the like, and thereafter, the natural oxide film formed on the surface of the n-type single crystal silicon substrate is removed by immersion of the n-type single crystal silicon substrate in hydrofluoric acid, and the surface of the n-type single crystal silicon substrate is terminated with hydrogen.

In a case of texturing the surface of the n-type single crystal silicon substrate, after the n-type single crystal silicon substrate is ultrasonically cleaned with ethanol or the like, the surface of the n-type single crystal silicon substrate is chemically anisotropically etched using an alkali, thereby texturing the surface of the n-type single crystal silicon substrate. Thereafter, the natural oxide film is removed using hydrofluoric acid as described above, and the surface of the n-type single crystal silicon substrate is terminated with hydrogen. Thereby, the silicon substrate 81 is prepared (refer to step (a) in FIG. 28).

The silicon substrate 81 is set on the sputtering device, and the passivation film 82 formed from SiO₂ is deposited on one surface of the silicon substrate 81 (refer to step (b) in FIG. 28), and thereafter the anti-reflection film 83 formed from Si₃N₄ is deposited on the passivation film 82 (refer to step (c) in FIG. 28).

Subsequently, a resist is coated on the other surface (=surface of the opposite side to the surfaced on which the passivation film 82 is formed) of the silicon substrate 81, and a resist pattern 92 is formed by patterning the resist thus coated by photolithography (refer to step (d) in FIG. 28).

The other surface of the silicon substrate 81 not covered by the resist pattern 92 is cleaned by hydrofluoric acid, the natural oxide film formed on the other surface of the silicon substrate 81 is removed, and the other surface of the silicon substrate 81 is terminated with hydrogen.

Thereafter, the sample (=anti-reflection film 83/passivation film 82/silicon substrate 81/resist pattern 92) is installed on the anode electrode 102 of the plasma device 100.

Thereby, the i-type semiconductor layers 93 and 94 formed from an i-type a-Si are deposited by plasma CVD method using the same formation conditions as the formation conditions of the i-type semiconductor layer 66 shown in Table 7 on the other surface of the silicon substrate 81 and the resist pattern 92, respectively (refer to step (e) in FIG. 28).

When the film thickness of the i-type semiconductor layers 93 and 94 is 5 nm to 30 nm, the n-type silicon thin films 95 and 96 are deposited by a plasma CVD method using the same formation conditions as the formation conditions of the n-type silicon thin film 71 shown in FIG. 7 on the i-type semiconductor layers 93 and 94, respectively (refer to step (f) in FIG. 28).

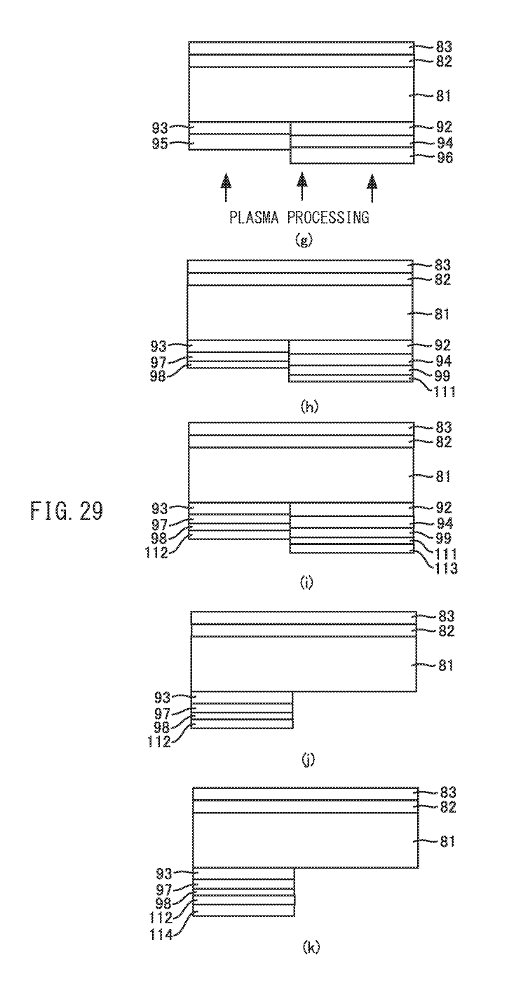

When the film thickness of the n-type silicon thin films 95 and 96 is the desired film thickness, the n-type silicon thin films 95 and 96 are plasma processed by a plasma CVD method using the same conditions as the plasma processing conditions shown in FIG. 7 (refer to step (g) in FIG. 29). Thereby, the n-type silicon thin films 97 and 98 are formed on the i-type semiconductor layer 93, and the n-type silicon thin films 99 and 111 are formed on the i-type semiconductor layer 94 (refer to step (h) in FIG. 29). In this case, the n-type silicon thin films 98 and 111 include nitrogen atoms.

When the plasma processing finishes, the n-type silicon thin films 112 and 113 are deposited by a plasma CVD method using the same formation conditions as the formation conditions of the n-type silicon thin film 673 shown in Table 7 on the n-type silicon thin films 98 and 111, respectively (refer to step (i) in FIG. 29).

The sample is removed from the plasma device 100, and the resist pattern 92 is removed. Thereby, the i-type semiconductor layer 94 and the n-type silicon thin films 99, 111 and 113 are removed by being lifted off (refer to step (j) in FIG. 29).

The overall film thickness of the n-type silicon thin films 97, 98, and 112 is 5 nm to 30 nm. The overall film thickness of the n-type silicon thin films 97 and 98 is the same as the film thickness of the n-type silicon thin film 95 deposited in step (f). Accordingly, the ratio of the overall film thickness of the n-type silicon thin films 97 and 98 and the film thickness of the n-type silicon thin film 112 is arbitrary.

After the step (j), the resist pattern 114 is formed by coating the resist on the n-type silicon thin film 112 (refer to step (k) in FIG. 29).

The other surface of the silicon substrate 81 on which the i-type semiconductor layer 93, the n-type silicon thin films 97, 98, and 112 and the resist pattern 114 are not formed is cleaned by hydrofluoric acid, the natural oxide film formed on the other surface of the silicon substrate 81 is removed, and the other surface of the silicon substrate 81 is terminated with hydrogen.

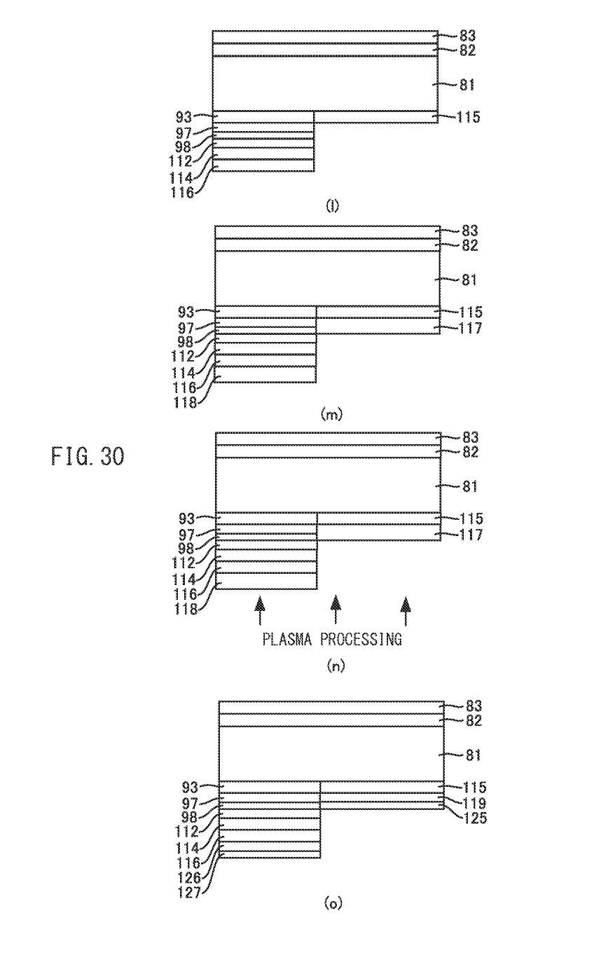

Thereafter, the sample is installed on the anode electrode 102 of the plasma device 100. The i-type semiconductor layers 115 and 116 formed from an i-type a-Si are deposited by plasma CVD method using the same formation conditions as the formation conditions of the i-type semiconductor layer 62 shown in Table 7 on the other surface of the silicon substrate 81 and the resist pattern 114, respectively (refer to step (l) in FIG. 30).

When the film thickness of the i-type semiconductor layers 115 and 116 is 5 nm to 30 nm, the p-type silicon thin films 117 and 118 are deposited by a plasma CVD method using the same formation conditions as the formation conditions of the p-type silicon thin film 70 shown in Table 7 on the i-type semiconductor layers 115 and 116, respectively (refer to step (m) in FIG. 30).

When the film thickness of the p-type silicon thin films 117 and 118 is the desired film thickness, the p-type silicon thin films 117 and 118 are plasma processed by a plasma CVD method using the same conditions as the plasma processing conditions shown in Table 7 (refer to step (n) in FIG. 30). Thereby, the p-type silicon thin film 119 and 125 are formed on the i-type semiconductor layer 115, and the p-type silicon thin films 126 and 127 are formed on the i-type semiconductor layer 116 (refer to step (o) in FIG. 30). In this case, the p-type silicon thin films 125 and 127 include nitrogen atoms.

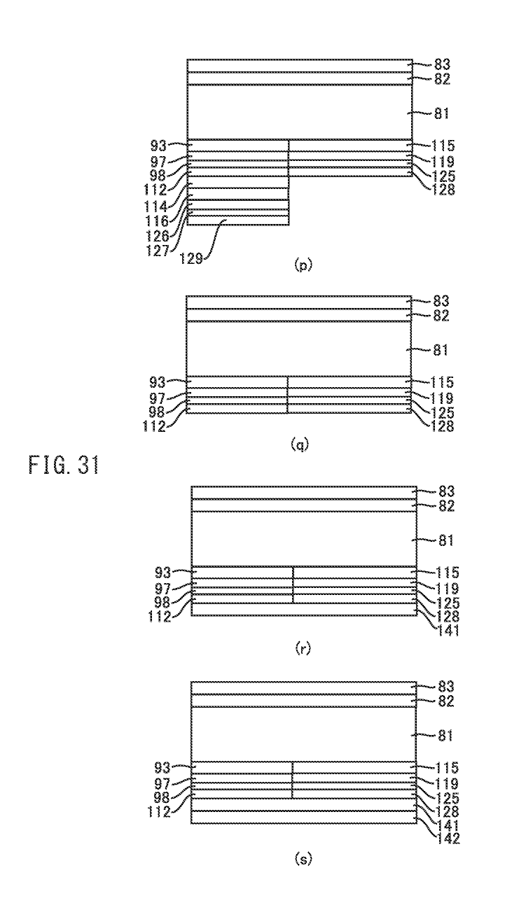

When the plasma processing finishes, the p-type silicon thin films 128 and 129 are deposited by a plasma CVD method using the same formation conditions as the formation conditions of the p-type silicon thin film 633 shown in Table 7 on the p-type silicon thin films 125 and 127, respectively (refer to step (p) in FIG. 31).

Then, the sample is removed from the plasma device 100, and the resist pattern 114 is removed. Thereby, the i-type semiconductor layer 116 and the p-type silicon thin films 126, 127 and 129 are removed by being lifted off (refer to step (q) in FIG. 31).

The p-type silicon thin films 119, 125, and 128 have an overall film thickness of 5 nm to 30 nm. The overall film thickness of the p-type silicon thin films 119 and 125 is the same as the film thickness of the p-type silicon thin film 117 deposited in step (m). Accordingly, the ratio of the overall film thickness of the p-type silicon thin films 119 and 125 and the film thickness of the p-type silicon thin film 128 is arbitrary.

After the step (q), the sample is set on the sputtering device. The transparent conductive film 141 formed from ZnO using the sputtering device is formed on the n-type silicon thin film 98 and the p-type silicon thin film 128 (refer to step (r) in FIG. 31). In this case, the film thickness of the transparent conductive film 141 is, for example, 50 to 150 nm.

Thereafter, the electrode 142 is formed on the transparent conductive film 141 through screen printing and firing of Ag (refer to step (s) in FIG. 31). In this case, the film thickness of the electrode 142 is, for example, 50 nm to 200 nm.

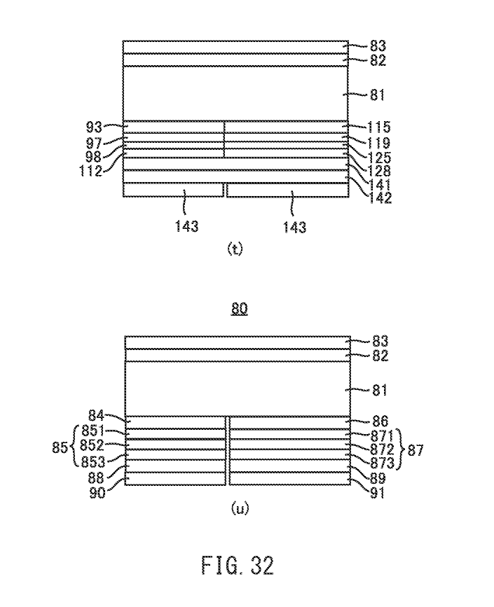

After the step (s), the resist is coated on the entire surface of the electrode 142, and the resist pattern 143 is formed by patterning the resist thus coated through photolithography (refer to step (t) in FIG. 32).

The i-type semiconductor layer 93 and 115, the n-type silicon thin films 97, 98, and 112, the p-type silicon thin films 119, 125, and 128, the transparent conductive film 141 and the electrode 142 are etched with the resist pattern 143 as a mask, and the resist pattern 143 is removed. Thereby, the photovoltaic device 80 is completed (refer to step (u) in FIG. 32).

As described above, the photovoltaic device 80, similarly to Embodiment 1, is manufactured with plasma generated using power PP in which a low frequency pulse power LP is superimposed on a high frequency power RF. As a result, discharge is stable, and it is possible to improve the in-plane uniformity of the nitrogen content in the n-type semiconductor layer 85 and the p-type semiconductor layer 87 in the plane of the photovoltaic device 80.

Accordingly, the open-circuit voltage Voc is improved by suppressing a lowering of the fill factor FF of the photovoltaic device 80.

Thereby, it is possible to improve the in-plane uniformity of nitrogen content concentration in a large-area photovoltaic device, and to improve the conversion efficiency of the photovoltaic device.

The silicon substrate 81 of the photovoltaic device 80 may be formed from an n-type polycrystalline silicon substrate. In this case, surface the light receiving surface side of the silicon substrate 81 is textured by etching. Also in a case in which the silicon substrate 81 is formed from an n-type polycrystalline silicon substrate, the photovoltaic device 80 is manufactured according to the steps (a) to (u) shown in FIGS. 28 to 32.

The silicon substrate 81 may be formed from a p-type single crystal silicon substrate or a p-type polycrystalline silicon substrate. In this case, the n-type semiconductor layer 85 is replaced by a p-type semiconductor layer formed from the same configuration as the p-type semiconductor layer 87, and the p-type semiconductor layer 87 is replaced by a n-type semiconductor layer formed from the same configuration as the n-type semiconductor layer 85. Also in a case in which the silicon substrate 81 is formed from a p-type single crystal silicon substrate or a p-type polycrystalline silicon substrate, the photovoltaic device 80 is manufactured according to the steps (a) to (u) shown in FIGS. 28 to 32.

In the photovoltaic device 80, at least one of the n-type semiconductor layer 85 and the p-type semiconductor layer 87 may be formed from a structure in which the silicon-based semiconductor layer including nitrogen atoms is interposed in the thickness direction between silicon-based semiconductor layers not including nitrogen atoms, or a structure in which a silicon-based semiconductor layer that has a first nitrogen atom concentration is interposed in the thickness direction between silicon-based semiconductor layers that have a second nitrogen atom concentration lower than the first nitrogen atom concentration. This is because it is possible to improve the open-circuit voltage Voc by suppressing a lowering of the fill factor FF if at least one of the n-type semiconductor layer 85 and the p-type semiconductor layer 87 is formed from such a structure.

The photovoltaic device 80 may not include the i-type semiconductor layers 84 and 86. This is because, even without the i-type semiconductor layers 84 and 86, if at least one of the n-type semiconductor layer 85 and the p-type semiconductor layer 87 has a structure in which the silicon-based semiconductor layer including nitrogen atoms is interposed in the thickness direction between silicon-based semiconductor layers not including nitrogen atoms, or a structure in which a silicon-based semiconductor layer that has a first nitrogen atom concentration is interposed in the thickness direction between silicon-based semiconductor layers that have a second nitrogen atom concentration lower than the first nitrogen atom concentration, it is possible to improve the open-circuit voltage Voc by suppressing a lowering of the fill factor FF.

In the above-described Embodiment 1, a photovoltaic device is described that includes at least one photovoltaic layer formed from a pin structure in which a p-type semiconductor layer, an i-type semiconductor layer and an n-type semiconductor layer are successively stacked on the substrate, in which at least one of the p-type semiconductor layer and the n-type semiconductor layer in at least one photovoltaic layer has a structure in which a layer including nitrogen atoms is interposed in the thickness direction between layers not including nitrogen atoms or a structure in which a layer that has a first nitrogen atom concentration is interposed in the thickness direction between layers that have a second nitrogen atom concentration lower than the first nitrogen atom concentration.

In the above-described Embodiment 2, a photovoltaic device is described that includes a silicon substrate, and a p-type semiconductor layer and an n-type semiconductor layer arranged on the silicon substrate, in which at least one of the p-type semiconductor layer and the n-type semiconductor layer has a structure in which a layer including nitrogen atoms is interposed in the thickness direction between layers not including nitrogen atoms or a structure in which a layer that has a first nitrogen atom concentration is interposed in the thickness direction between layers that have a second nitrogen atom concentration lower than the first nitrogen atom concentration. In the photovoltaic device, the p-type semiconductor layer, the n-type semiconductor layer, and the silicon substrate configure the photovoltaic portion that converts light to electricity.

Accordingly, the photovoltaic device according to the embodiment of the invention that includes a photovoltaic portion that converts light to electricity, may include a substrate; and a silicon-based semiconductor layer formed with the substrate as a support base body, and configures the photovoltaic portion, in which the silicon-based semiconductor layer includes a first silicon-based semiconductor layer that has a p-type conductivity type, a second silicon-based semiconductor layer that has an n-type conductivity type, and a third silicon-based semiconductor layer that has an i-type conductivity type, in which at least one of the first and second silicon-based semiconductor layers has a structure in which a layer including nitrogen atoms is interposed in the thickness direction between layers not including nitrogen atoms or a structure in which a layer that has a first nitrogen atom concentration is interposed in the thickness direction between layers that have a second nitrogen atom concentration lower than the first nitrogen atom concentration.

This is because if at least one of the first and second silicon-based semiconductor layers has a structure in which a layer including nitrogen atoms is interposed in the thickness direction between layers not including nitrogen atoms or a structure in which a layer that has a first nitrogen atom concentration is interposed in the thickness direction between layers that have a second nitrogen atom concentration lower than the first nitrogen atom concentration, it is possible to improve the open-circuit voltage Voc by suppressing a lowering of the fill factor FF, thereby improving the conversion efficiency of the photovoltaic device.

In Embodiment 1, a method for manufacturing a photovoltaic device having a pin structure is described that includes depositing the p-type silicon thin film or the n-type silicon thin film on the substrate, irradiating the p-type silicon thin film or the n-type silicon thin film thus deposited with plasma employing N₂ gas, and thereafter, forming the p-type semiconductor layer or the n-type semiconductor layer by depositing the p-type silicon thin film or the n-type silicon thin film on the p-type silicon thin film or the n-type silicon thin film irradiated by plasma. The plasma employing N₂ gas is generated using a pulse power PP in which a low frequency pulse power LP of 100 Hz to 1 kHz is superimposed on a high frequency power RF of 1 MHz to 50 MHz, the density of the high frequency power is 100 mW/cm² to 300 mW/cm², the pressure during plasma processing is 300 Pa to 600 Pa, and the substrate temperature during plasma processing is 140° C. to 190° C.

In Embodiment 2, a method for manufacturing the photovoltaic device that has a silicon substrate using the formation method of the p-type semiconductor layer or the n-type semiconductor layer in Embodiment 1 will be described.

Accordingly, the method for manufacturing a photovoltaic device according to the embodiment of the invention is a method using plasma CVD that includes a first plasma processing step of depositing the first silicon-based semiconductor layer that has a p-type conductivity type or an n-type conductivity type above the substrate; a second plasma processing step of irradiating the first silicon-based semiconductor layer with plasma in which a raw material gas including nitrogen atoms is excited; a third plasma processing step of depositing a second silicon-based semiconductor layer that has the same conductivity type as the first silicon-based semiconductor layer on the first silicon-based semiconductor layer, in which the second plasma processing step uses pulsed power in which a low frequency pulse power of 100 Hz to 1 kHz is superimposed on a high frequency power of 1 MHz to 50 MHz as a plasma excitation power, and the density of the high frequency power may be 100 mW/cm² to 300 mW/cm², the pressure during the plasma processing may be 300 Pa to 600 Pa, and the substrate temperature during plasma processing may be 140° C. to 190° C.

For the photovoltaic device according to Embodiment 2, the distribution of the nitrogen concentration and the boron concentration in the depth direction of the photovoltaic device with the structure shown in FIG. 23 is measured using a secondary ion mass spectrometry (SIMS) method. The measurement results are not shown; however, it is understood that nitrogen concentration is lower than 5×10¹⁸ (units/cm⁻³), similarly to FIG. 22, and the p-type silicon thin film 632 including a high concentration of nitrogen of 1×10¹⁹ (units/cm⁻³) or more is interposed by the p-type silicon thin films 631 and 633 to which nitrogen is substantially not added.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

### INDUSTRIAL APPLICABILITY

The present invention is applied to a photovoltaic device and a method for manufacturing the same.

1. A photovoltaic device that includes a photovoltaic portion that converts light to electricity, the photovoltaic device comprising:
a substrate; and
a silicon-based semiconductor layer formed with the substrate as a support base body and configuring the photovoltaic portion,
wherein the silicon-based semiconductor layer includes
a first silicon-based semiconductor layer that has a p-type conductivity type,
a second silicon-based semiconductor layer that has an n-type conductivity type, and
a third silicon-based semiconductor layer that has an i-type conductivity type, and
wherein at least one of the first and second silicon-based semiconductor layers has a structure in which a layer including nitrogen atoms is interposed in a thickness direction between layers not including nitrogen atoms or a structure in which a layer having a first nitrogen atom concentration is interposed in the thickness direction between layers having a second nitrogen atom concentration lower than the first nitrogen atom concentration.

2. The photovoltaic device according to claim 1,
wherein the substrate includes
an insulating support body as a support body of the photovoltaic portion, and
a transparent conductive film arranged on the insulating support body in contact with the insulating support body.

3. The photovoltaic device according to claim 2,
wherein the insulating support body is formed from a light-transmitting substrate, and
wherein the transparent conductive film is arranged between the light-transmitting substrate and the first silicon-based semiconductor layer.

4. The photovoltaic device according to claim 2,
wherein the insulating support body is formed from a non-light-transmitting substrate, and
wherein the transparent conductive film is arranged between the non-light-transmitting substrate and the second silicon-based semiconductor layer.

5. The photovoltaic device according to claim 1,
wherein the substrate is formed from a silicon substrate, and
wherein the first silicon-based semiconductor layer is arranged on the opposite side to the second silicon-based semiconductor layer with respect to the silicon substrate.

6. The photovoltaic device according to claim 1,
wherein the substrate is formed from a silicon substrate,
wherein the first silicon-based semiconductor layer is arranged on one side of the silicon substrate, and
wherein the second silicon-based semiconductor layer is arranged neighboring the first silicon-based semiconductor layer in the in-plane direction of the silicon substrate.

7. A method for manufacturing a photovoltaic device by a plasma CVD method, the method comprising:
a first plasma processing step of depositing the first silicon-based semiconductor layer that has a p-type conductivity type or an n-type conductivity type above the substrate;
a second plasma processing step of irradiating the first silicon-based semiconductor layer with plasma in which a raw material gas including nitrogen atoms is excited; and
a third plasma processing step of depositing a second silicon-based semiconductor layer that has the same conductivity type as the first silicon-based semiconductor layer on the first silicon-based semiconductor layer,
wherein the second plasma processing step uses pulsed power in which a low frequency pulse power of 100 Hz to 1 kHz is superimposed on a high frequency power of 1 MHz to 50 MHz as a plasma excitation power,
wherein the density of the high frequency power is 100 mW/cm² to 300 mW/cm²,
wherein the pressure during the plasma processing is 300 Pa to 600 Pa, and
wherein the substrate temperature during plasma processing is 140° C. to 190° C.

8. The method for manufacturing a photovoltaic device according to claim 7,
wherein the duty ratio of the low frequency pulse is 0.1 to 0.5.

9. The method for manufacturing a photovoltaic device according to claim 7,
wherein the plasma irradiation time in the second plasma processing step is 5 to 60 seconds.

10. The method for manufacturing a photovoltaic device according to claim 7,
wherein the first to third plasma processing steps are executed in the same processing chamber.

11. The method for manufacturing a photovoltaic device according to claim 7,
wherein the first to third plasma processing steps are executed at the same processing pressure.

12. The method for manufacturing a photovoltaic device according to claim 7,
wherein the first and second silicon-based semiconductor layers are microcrystalline silicon semiconductor layers.

13. The method for manufacturing a photovoltaic device according to claim 7,
wherein a silicon-based semiconductor layer having a p-type conductivity type is deposited in the first and third plasma processing steps.

14. The method for manufacturing a photovoltaic device according to claim 7, further comprising:
a fourth plasma processing step, in which a microcrystalline silicon having an intrinsic conductivity type is deposited, after the silicon-based semiconductor layer having a p-type conductivity type is deposited by the first to third plasma processing steps.

15. The method for manufacturing a photovoltaic device according to claim 7,
wherein the pin-type photovoltaic portion that has a p-type conductivity type layer manufactured using the first to third plasma processing steps is manufactured in the same processing chamber.

16. The method for manufacturing a photovoltaic device according to claim 7,
wherein the processing chamber in which the plasma processing step is executed has a pair of a cathode electrode and an anode electrode that are supplied with the plasma excitation power, and
wherein the size of the cathode electrode and the anode electrode is 1 m² to 3 m² with respect to one photovoltaic portion.

17. The method for manufacturing a photovoltaic device according to claim 7,
wherein the processing chamber in which the plasma processing step is executed has a plurality of pairs of cathode electrodes and anode electrodes, and
wherein one power source supplies plasma excitation power to the plurality of pairs of cathode electrodes and the anode electrodes.
